(19) United States
(12) Patent Application Publication
(10) Pub. No.: US 2025/0048901 A1
(43) Pub. Date: Feb. 6, 2025

(54) DISPLAY DEVICE

(71) Applicant: Samsung Display Co., Ltd., Yongin-Si (KR)

(72) Inventors: Soo Yeong HONG, Yongin-si (KR); Jung Suk BANG, Yongin-si (KR); Kwang Soo BAE, Yongin-si (KR)

(21) Appl. No.: 18/664,322

(22) Filed: May 15, 2024

(30) Foreign Application Priority Data
Aug. 1, 2023 (KR) 10-2023-0100447

(51) Int. Cl. H10K 59/80; H10K 39/34

(52) U.S. Cl. CPC H10K 59/8791; H10K 39/34

(57) ABSTRACT

A display device according to an embodiment includes an active area including an emission area and a sensing area, an optical element layer including a light emitting element located in the emission area and a photoelectric conversion element located in the sensing area, a light blocking member disposed on the optical element layer, and including a first opening disposed in an area corresponding to the emission area and a second opening disposed in an area corresponding to the sensing area, a color filter located in the first opening and overlapping the light emitting element, and an optical filter located in the second opening and overlapping the photoelectric conversion element, wherein the optical filter is entirely disposed in the second opening and has a thickness smaller than that of the color filter.

### CROSS-REFERENCE TO RELATED APPLICATION

This application claims priority to Korean Patent Application No. 10-2023-0100447 filed on Aug. 1, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device.

### 2. Description of the Related Art

The importance of display devices has steadily increased with the development of multimedia technology. Accordingly, various types of display devices such as a liquid crystal display device, an organic light emitting display device or the like have been developed.

### SUMMARY

Aspects of the present disclosure provide a display device including a photoelectric conversion element with improved reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including an active area including an emission area and a sensing area, an optical element layer including a light emitting element located in the emission area and a photoelectric conversion element located in the sensing area, a light blocking member disposed on the optical element layer, and including a first opening disposed in an area corresponding to the emission area and a second opening disposed in an area corresponding to the sensing area, a color filter located in the first opening and overlapping the light emitting element, and an optical filter located in the second opening and overlapping the photoelectric conversion element, wherein the optical filter is entirely disposed in the second opening and has a thickness smaller than that of the color filter.

In an embodiment, the optical filter may include a metal thin film transmitting light corresponding to a wavelength band of light emitted from the emission area.

In an embodiment, the metal thin film may have a thickness of 10 nm or less.

In an embodiment, the metal thin film may contain at least one metal selected from the group consisting of copper (Cu), gold (Au), silver (Ag), nickel (Ni), titanium (Ti), vanadium (V), and aluminum (Al).

In an embodiment, the display device may further include a pixel including the light emitting element and emitting light of a first color in the emission area, the color filter may be a color filter of the first color which selectively transmits light of the first color, and the optical filter may include a color filter of the first color which selectively transmits light of the first color.

In an embodiment, the pixel may emit green light, and the color filter and the optical filter may be green color filters.

In an embodiment, the active area may include a pixel column in which the pixel and another pixel which emit light of the first color are arranged, and the sensing area may be disposed between the emission areas of the pixel and the another pixel.

In an embodiment, the color filter and the optical filter may be disposed on a same layer above the optical element layer.

In an embodiment, the display device may further include a panel circuit layer disposed below the optical element layer, and including a pixel transistor connected to the light emitting element and a sensor transistor connected to the photoelectric conversion element, and a substrate disposed below the panel circuit layer.

In an embodiment, the light emitting element and the photoelectric conversion element may be disposed on a same layer above the substrate.

According to an aspect of the present disclosure, there is provided a display device including a first pixel including a light emitting element located in a first emission area, an optical sensor including a photoelectric conversion element located in a sensing area disposed adjacent to the first emission area, a first color filter located in the first emission area and disposed on the light emitting element, and an optical filter located in the sensing area and disposed on the photoelectric conversion element, wherein the optical filter entirely covers a light receiving part of the optical sensor disposed corresponding to the sensing area, and has a thickness smaller than that of the first color filter.

In an embodiment, the optical filter may include a metal thin film transmitting light corresponding to a wavelength band of light emitted from the first emission area.

In an embodiment, the metal thin film may have a thickness of 10 nm or less.

In an embodiment, the metal thin film may contain at least one metal selected from the group consisting of copper (Cu), gold (Au), silver (Ag), nickel (Ni), titanium (Ti), vanadium (V), and aluminum (Al).

In an embodiment, the display device may further include a second pixel including a light emitting element located in a second emission area, a third pixel including a light emitting element located in a third emission area, a second color filter located in the second emission area and disposed on the second pixel, and a third color filter located in the third emission area and disposed on the third pixel. The first pixel, the second pixel, and the third pixel may emit light of a first color, light of a second color, and light of a third color, respectively, and the first color filter, the second color filter, and the third color filter may be color filters which selectively transmit light of the first color, light of the second color, and light of the third color, respectively.

In an embodiment, the optical filter may include a fourth color filter which selectively transmits one of light of the first color, light of the second color, and light of the third color and may have a thickness smaller than those of the first color filter, the second color filter, and the third color filter.

In an embodiment, the display device may further include an optical element layer including the light emitting element and the photoelectric conversion element, an optical filter layer disposed on the optical element layer, and including the first color filter and the optical filter, and a substrate disposed below the optical element layer. The first color filter and the optical filter may be disposed on a same layer on a surface of the substrate.

In an embodiment, the display device may further include a light blocking member provided in the optical filter layer, and surrounding the first emission area and the sensing area in a plan view.

In an embodiment, the light blocking member may include a first opening disposed in an area corresponding to the first emission area and a second opening disposed in an area corresponding to the sensing area, the first color filter may be entirely disposed in the first opening, and the optical filter may be entirely disposed in the second opening.

In an embodiment, the optical filter may have a thickness smaller than that of the light blocking member.

A display device according to embodiments includes a photoelectric conversion element and an optical filter disposed on the photoelectric conversion element. The optical filter may be a thin film having a thickness smaller than that of a color filter disposed on a light emitting element located in an emission area, and may be, for example, a metal thin film or a color filter.

In accordance with embodiments, it is possible to reduce or alleviate deterioration of the photoelectric conversion element while ensuring a sufficient amount of light received by the photoelectric conversion element. Accordingly, the reliability of the photoelectric conversion element and the optical sensor including the same may be increased.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to one embodiment;

FIG. 2 is a block diagram of a display device according to one embodiment;

FIG. 3 is a cross-sectional view showing a schematic cross section of an active area of the display device according to one embodiment, and a method for sensing a fingerprint of a finger;

FIG. 4 is a cross-sectional view showing a schematic cross section of the active area of the display device according to one embodiment, and a method for sensing a fingerprint of a finger;

FIG. 5 is a circuit diagram of a pixel and an optical sensor according to one embodiment;

FIG. 6 is a plan view showing the arrangement structure of the pixels, the optical sensors, the color filters and the optical filters according to one embodiment;

FIG. 7 is a plan view showing the arrangement structure of the pixels, the optical sensors, the color filters and the optical filters according to one embodiment;

FIG. 8 is a plan view showing the pixels, the optical sensors, and the light blocking member according to one embodiment;

FIG. 9 is a cross-sectional view showing an example of a cross section of the display device taken along line I-I′ of FIGS. 6 and 8;

FIG. 10 is a cross-sectional view showing an example of a cross section of the display device taken along line II-II′ of FIGS. 7 and 8;

FIGS. 11, 12 and 13 are graphs showing the light transmittance or the light absorption rate according to the material and the thickness of the optical filter;

FIG. 14 is a cross-sectional view showing an example of a cross section of the display device taken along line I-I′ of FIGS. 6 and 8; and

FIG. 15 is a cross-sectional view showing an example of a cross section of the display device 1 taken along line II-II′ of FIGS. 7 and 8.

### DETAILED DESCRIPTION OF THE EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

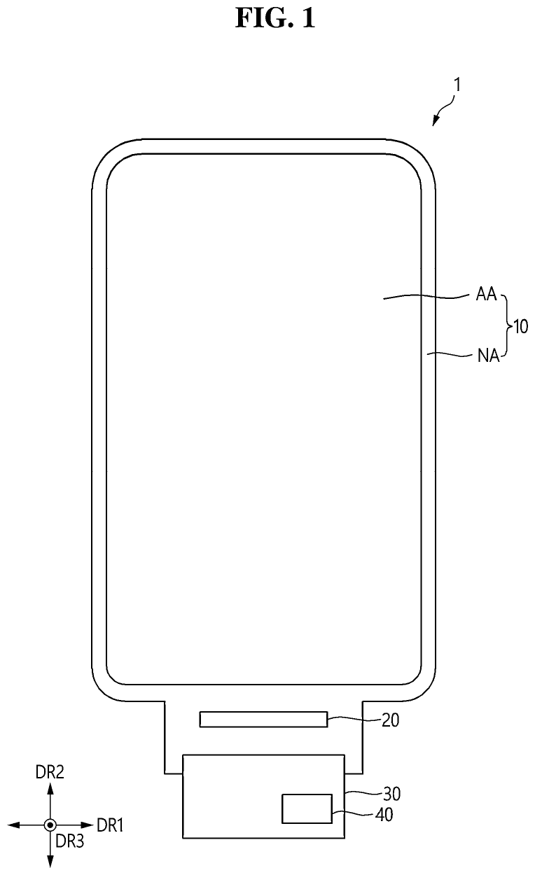

FIG. 1 is a plan view illustrating a display device 1 according to one embodiment.

In FIG. 1, a first direction DR1, a second direction DR2, and a third direction DR3 are indicated. The first direction DR1 may be a direction parallel to one side of the display device 1 in a plan view and may be, for example, a horizontal direction of the display device 1. The second direction DR2 may be a direction parallel to the other side in contact with one side of the display device 1 in a plan view and may be, for example, a vertical direction of the display device 1. The third direction DR3 may be a thickness direction (or height direction) of the display device 1. However, a direction mentioned in the following embodiments may refer to a relative direction, and the embodiments are not limited thereto.

Further, in the embodiments, the term “above” or “top surface” expressed with respect to the third direction DR3 may refer to a display surface side of a display panel 10, and the term “below,” “bottom surface,” or “rear surface” may refer to a side opposite to the display surface of the display panel 10. However, according to the direction facing the display panel 10 or the display device 1 including the same, the defined direction may be changed to the opposite direction or the like.

Referring to FIG. 1, the display device 1 may be one of various electronic devices providing a display surface on which an image is displayed. For example, the display device 1 may one of various electronic devices including a mobile phone, a smart phone, a tablet personal computer (PC), a mobile communication terminal, an electronic notebook, an electronic book, a personal digital assistant (PDA), a portable multimedia player (PMP), a navigation device, an ultra-mobile PC (UMPC), a television, a game console, a wrist watch type electronic device, a head-mounted display, a personal computer monitor, a laptop computer, a car dashboard, a digital camera, a camcorder, an external billboard, an electric billboard, various medical devices, various inspection devices, various home appliances including a display area such as a refrigerator or a washing machine, an Internet-of-Things (IoT) device, and the like. A typical example of the display device 1 to be described later may be a smart phone, a tablet PC, or a laptop computer, but the display device 1 according to the embodiments is not limited thereto.

The display device 1 may include the display panel 10, a driving circuit 20, a circuit board 30, and a read-out circuit 40 (e.g., a read-out IC).

The display panel 10 may include an active area AA and a non-active area NA. In one embodiment, the display panel 10 may be formed to be partially or entirely flexible, and may be transformed to be folded, bent, or rolled in at least one portion. For example, the display panel 10 may be folded or bent in the non-active area NA, so that a part of the non-active area NA on which the driving circuit 20 or the like is mounted may be positioned on the opposite side (for example, the rear surface side of the display device 1) of the display surface.

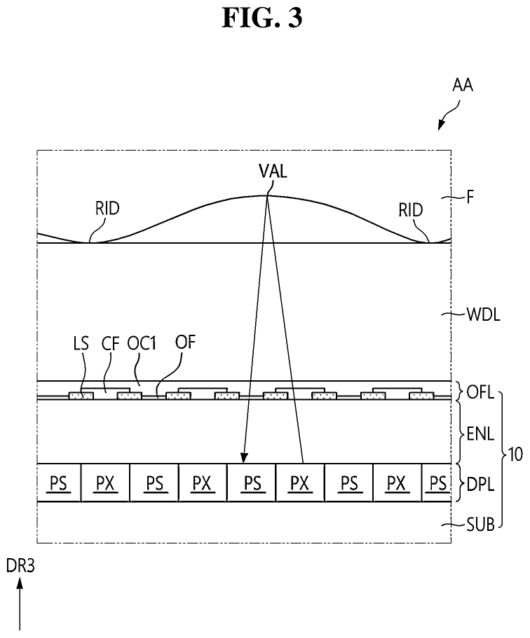

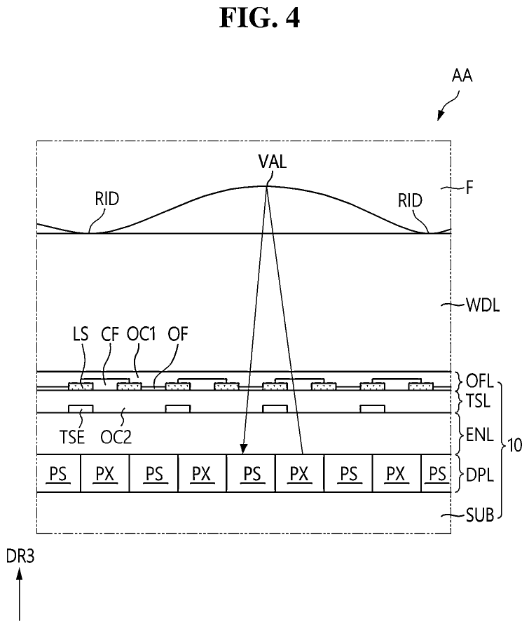

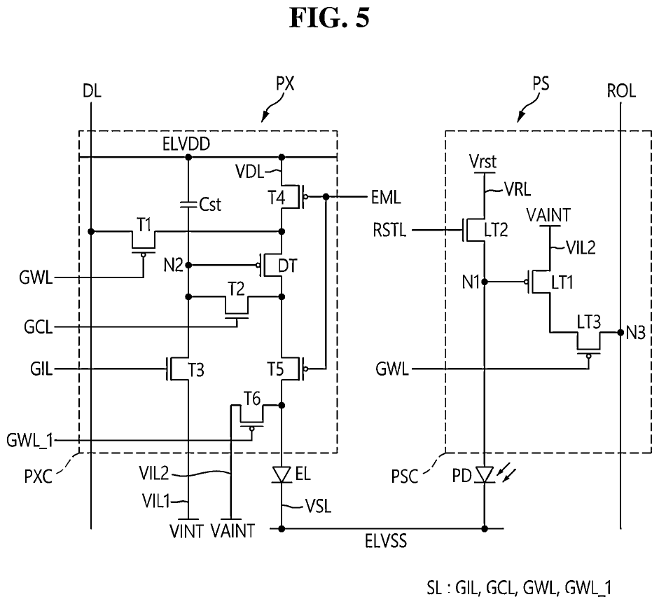

The active area AA may include a display area. For example, the active area AA may completely overlap the display area. Pixels (for example, pixels PX of FIG. 3 or 4) for displaying an image may be disposed in the active area AA (or the display area). For example, the active area AA may include pixel areas where pixels are arranged or provided. Each pixel area may include an emission area. In one embodiment, a light emitting element (for example, a light emitting element EL of FIG. 5) may be disposed in each emission area.

The active area AA may further include a sensing area that responds to light. For example, the active area AA may further include a sensing area (for example, a light sensing area) for sensing the amount or wavelength of incident light. In one embodiment, the sensing area may include a fingerprint sensing area for sensing a user's fingerprint using optical sensors. For example, optical sensors (for example, optical sensors PS of FIG. 3 or 4) may be disposed in the active area AA. Each optical sensor may include a photoelectric conversion element (for example, a photoelectric conversion element PD of FIG. 5). The photoelectric conversion element may sense incident light and convert it into an electrical signal.

For example, the active area AA may include the optical sensors including respective photoelectric conversion elements. The optical sensors may output sensing signals corresponding to incident light, and may sense a user's input (for example, a fingerprint input) provided in the active area AA using the sensing signals.

In one embodiment, the sensing area may overlap the display area. For example, the sensing area may be a part of the display area or may be substantially the same area as the display area. In this case, the sensing area may be a part of the active area AA, or may be the entire active area AA.

The non-active area NA may include a non-display area, and may be located around the active area AA. The non-active area NA may be located on at least one side of the active area AA, and may partially or entirely surround the active area AA. Signal lines, pads, and/or the driving circuit 20 electrically connected to the pixels and/or the optical sensors in the active area AA may be disposed in the non-active area NA.

The driving circuit 20 may be electrically connected to the pixels and the optical sensors in the active area AA to drive the pixels and the optical sensors. For example, the driving circuit 20 may generate driving signals and/or power voltages for driving the pixels and the optical sensors, and may output the driving signals and/or the power voltages to the pixels and the optical sensors. For example, the driving circuit 20 may include at least one of a gate driving circuit (or a part of the gate driving circuit) including a scan driver or a source driving circuit (or a part of the source driving circuit) including a data driver.

The driving circuit 20 may be formed as an integrated circuit (IC) and mounted on the display panel 10, or may be mounted on the circuit board 30 connected to the display panel 10. In one embodiment, the driving circuit 20 may be provided outside the active area AA. In another embodiment, at least a part of the driving circuit 20 (for example, at least a part of the scan driver) may be provided inside the active area AA, and may be formed together with pixels.

The circuit board 30 may be connected to or attached to one end of the display panel 10. For example, the circuit board 30 may be attached to one end of the display panel 10 using an anisotropic conductive film (ACF). Lead lines of the circuit board 30 may be electrically connected to a pad unit of the display panel 10. In one embodiment, the circuit board 30 may be a flexible film such as a flexible printed circuit board (FPCB) or a chip on film (COF).

The read-out circuit 40 may be electrically connected to the optical sensors disposed in the active area AA. The read-out circuit 40 may receive the electrical signal corresponding to the current flowing through the optical sensors. The read-out circuit 40 may convert the electrical signal received from the optical sensors and transmit it to the processor (for example, the processor provided in a host device or the display device 1) connected to the read-out circuit 40, or may execute a designated function based on the electrical signal.

In one embodiment, the read-out circuit 40 may be formed as an integrated circuit (IC) and attached on the circuit board 30 by a chip on film (COF) method, but the embodiments are not limited thereto. For example, the read-out circuit 40 may be attached to the non-active area NA of the display panel 10 by a chip on glass (COG) method, a chip on plastic (COP) method, or an ultrasonic bonding method.

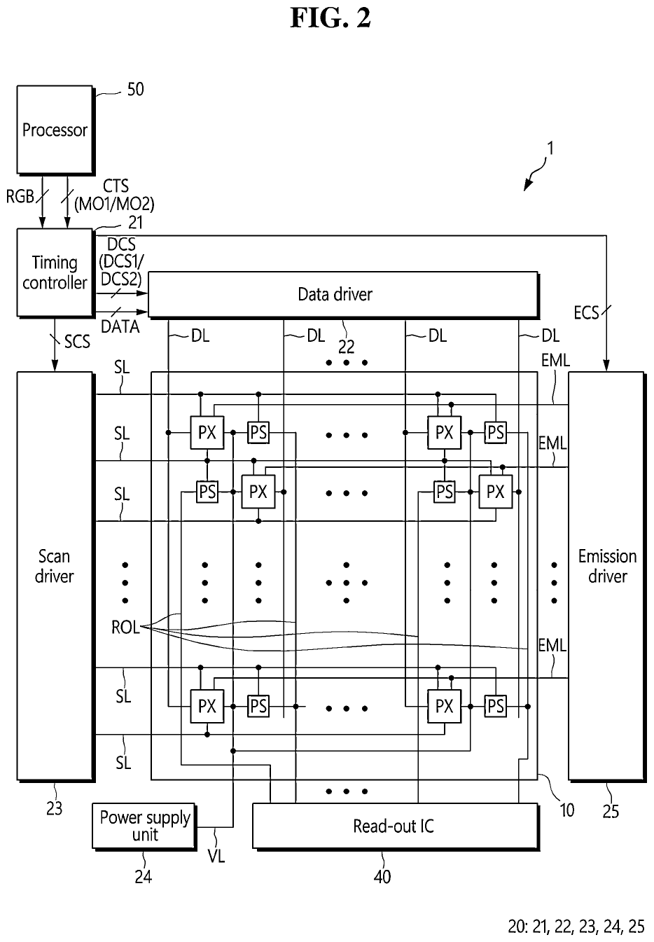

FIG. 2 is a block diagram of a display device according to one embodiment.

Referring to FIG. 2 in addition to FIG. 1, the display device 1 may include the display panel 10, the driving circuit 20, the read-out circuit 40, and a processor 50. Although FIG. 2 discloses an embodiment in which the processor 50 is provided in the display device 1, the embodiments are not limited thereto. For example, the processor 50 may be provided in the host device connected to the display device 1.

The display panel 10 may include the pixels PX and the optical sensors PS disposed in the active area AA, scan lines SL and power voltage lines VL connected (for example, electrically connected) to the pixels PX and the optical sensors PS, data lines DL and emission control lines EML connected to the pixels PX, and read-out lines ROL connected to the optical sensors PS.

Each pixel PX may be connected to at least one scan line SL, one data line DL, one emission control line EML, and at least one power voltage line VL.

Each optical sensor PS may be connected to at least one scan line SL, one read-out line ROL, and at least one power voltage line VL. In one embodiment, the optical sensors PS may be disposed between the pixels PX, and may be formed inside the display panel 10 together with the pixels PX. For example, the optical sensors PS may be formed or disposed between the pixels PX located in the active area AA.

The scan lines SL may connect the pixels PX and the optical sensors PS to the scan driver 23. The scan lines SL may transmit or provide scan signals outputted from the scan driver 23 to the pixels PX and the optical sensors PS.

The data lines DL may connect the pixels PX to the data driver 22. The data lines DL may transmit or provide respective data signals outputted from the data driver 22 to the pixels PX.

The emission control lines EML may connect the pixels PX to an emission control driver 25. The emission control lines EML may transmit or provide emission control signals outputted from the emission control driver 25 to the pixels PX.

The read-out lines ROL may connect the optical sensors PS to the read-out circuit 40. The read-out lines ROL may transmit or provide electrical signals (for example, sensing currents or sensing signals) generated according to photoelectric currents outputted from the optical sensors PS to the read-out circuit 40. Accordingly, the read-out circuit 40 may sense a user input (for example, a fingerprint input).

The power voltage lines VL may connect the pixels PX and the optical sensors PS to a power supply unit 24. For example, the power voltage lines VL may transmit or provide a first power voltage (for example, a first power voltage ELVDD of FIG. 5), a second power voltage (for example, a second power voltage ELVSS of FIG. 5) and/or other power voltages, which are generated or outputted from the power supply unit 24, to the pixels PX and the optical sensors PS. FIG. 2 illustrates that one power voltage line VL is provided in the display panel 10, but the power voltage lines VL corresponding to the type and/or number of power voltages required to drive the pixels PX and the optical sensors PS may be provided or formed in the display panel 10.

The driving circuit 20 may include a data driver 22 for driving the pixels PX, a scan driver 23 for driving the pixels PX and the optical sensors PS, and a timing controller 21 for controlling driving timing of the data driver 22 and the scan driver 23. In one embodiment, the driving circuit 20 may further include the power supply unit 24 for generating and/or transmitting power voltages for driving the pixels PX and the optical sensors PS, and/or the emission control driver 25 for driving the pixels PX.

The timing controller 21 may receive an image signal RGB and control signals CTS from the processor 50. The timing controller 21 may output image data DATA, a data control signal DCS, a scan control signal SCS, and an emission control driving signal ECS based on the image signal RGB and the control signals CTS. The image data DATA and the data control signal DCS may be supplied to the data driver 22. The scan control signal SCS and the emission control driving signal ECS may be supplied to the scan driver 23 and the emission control driver 25, respectively.

In one embodiment, the control signals CTS may include a first mode control signal MO1 and a second mode control signal MO2. The timing controller 21 may generate a first data control signal DCS1 when the first mode control signal MO1 is supplied, and may generate a second data control signal DCS2 when the second mode control signal MO2 is supplied.

The data driver 22 may generate data signals corresponding to the image data DATA, and may output the data signals to the data lines DL. For example, the data driver 22 may convert the image data DATA into analog data voltages and may output them to the data lines DL. The data signals may be supplied to the pixels PX through the data lines DL.

The scan driver 23 may generate scan signals in response to the scan control signal SCS, and may output the scan signals to the scan lines SL. The scan signals may be supplied to the pixels PX and the optical sensors PS through the scan lines SL.

The power supply unit 24 may generate at least one power voltage for driving the pixels PX and the optical sensors PS, and may output the at least one power voltage to at least one power voltage line VL. The at least one power voltage may be supplied to the pixels PX and the optical sensors PS through the power voltage line VL.

The emission control driver 25 may generate emission control signals in response to the emission control driving signal ECS, and may output the emission control signals to the emission control lines EML. The emission control driver 25 may be formed or provided separately from the scan driver 23, or may be integrated into the scan driver 23.

The read-out circuit 40 may be connected to the optical sensors PS through the read-out lines ROL, and may receive electrical signals (for example, currents flowing through optical sensor PS) corresponding to the amount of light received by the optical sensors PS. The read-out circuit 40 may generate data, for example, digital sensing data, corresponding to the magnitude of the electrical signals inputted from optical sensor PS and may transmit them to the processor 50. In the case of sensing a user's fingerprint using the electrical signal from the optical sensors PS, the processor 50 may analyze the digital sensing data to determine whether or not the digital sensing data is the same as a pre-registered user's fingerprint. When the pre-registered fingerprint and the digital sensing data transmitted from the read-out circuit 40 are the same, preset functions may be performed.

The processor 50 may supply the image signal RGB and the control signals CTS supplied from the outside to the timing controller 21. The processor 50 may further include a graphic processing unit (hereinafter, referred to as GPU) that provides graphics for the image signal RGB. The image signal RGB, which is an image source that has been subjected to graphic processing in the GPU, may be provided to the timing controller 21. The image signal RGB may have a specific frequency (for example, a frequency of 120 Hz or 30 Hz).

The control signals CTS outputted from the processor 50 may include the first mode control signal MO1, the second mode control signal MO2, a clock signal, an enable signal, and the like. The first mode control signal MO1 may include a display mode signal for displaying a normal image. The second mode control signal MO2 may include a sensing mode signal for sensing a user's fingerprint or the like. In one embodiment, the second mode control signal MO2 may be a signal that causes at least some pixels PX (for example, green pixels) to emit light during a period in which the sensing mode is executed. Accordingly, a user's fingerprint or the like may be sensed while using the pixels PX as a light source.

The processor 50 may supply the first mode control signal MO1 to the timing controller 21 in order to display an image on the display panel 10. The processor 50 may supply the second mode control signal MO2 to the timing controller 21 in order to sense a user's fingerprint or the like. The timing controller 21 may drive the pixels PX of the display panel 10 in response to the first mode control signal MO1. The timing controller 21 may drive the pixels PX and the optical sensors PS of the display panel 10 in response to the second mode control signal MO2.

FIG. 3 is a cross-sectional view showing a schematic cross section of the active area AA of the display device 1 according to one embodiment, and a method for sensing a fingerprint of a finger F. FIG. 3 illustrates the method for sensing the fingerprint of the finger F located on the first active area AA of the display device 1.

Referring to FIG. 3 in addition to FIGS. 1 and 2, the display device 1 may include the display panel 10, and a window WDL disposed on the display panel 10. The display panel 10 may include a substrate SUB, a display layer DPL disposed on the substrate SUB, and an encapsulation layer ENL and an optical filter layer OFL disposed on the display layer DPL.

The substrate SUB may be a base member for forming or arranging components of the display panel 10. The substrate SUB may include the active area AA and the non-active area NA. For example, an area corresponding to a part of the substrate SUB may be defined as the active area AA, and an area corresponding to the other part of the substrate SUB may be defined as the non-active area NA.

The display layer DPL may include the pixels PX and the optical sensors PS disposed on the substrate SUB. The pixels PX and the optical sensors PS may be disposed and/or formed on the substrate SUB to be located in the active area AA.

For simplicity, FIG. 3 illustrates an embodiment in which the pixels PX and the optical sensors PS are alternately arranged one by one along at least one direction (for example, the first direction DR1 and/or the second direction DR2 intersecting the third direction DR3), but the arrangement structure, number, and/or resolution of the pixels PX and the optical sensors PS may be variously changed according to embodiments.

In one embodiment, the pixels PX and the optical sensors PS may be formed simultaneously. For example, after a pixel circuit (for example, a pixel circuit PXC of FIG. 5) of each of the pixels PX and an optical sensor circuit (for example, an optical sensor circuit PSC of FIG. 5) of each of the optical sensors PS are simultaneously formed on the substrate SUB, a light emitting element (for example, the light emitting element EL of FIG. 5) of each of the pixels PX and a photoelectric conversion element (for example, the photoelectric conversion element PD of FIG. 5) of each of the optical sensors PS (or at least a part of the light emitting element and at least a part of the photoelectric conversion element) may be simultaneously formed on the substrate SUB on which the pixel circuit and the optical sensor circuit are formed.

As in the embodiment, the display device 1 in which the optical sensors PS are disposed or formed inside the display panel 10 together with the pixels PX may have a reduced thickness compared to a display device of a comparative example in which separately provided optical sensors are disposed or attached on one side of a display panel. Further, the display device 1 according to the embodiment may increase the amount of light received by the optical sensors PS compared to the display device of the comparative example.

The encapsulation layer ENL may be disposed and/or formed on the display layer DPL to cover at least the pixels PX and the optical sensors PS. The encapsulation layer ENL may protect the pixels PX and the optical sensors PS.

The optical filter layer OFL may be located above the pixels PX and the optical sensors PS. For example, the optical filter layer OFL may be located on the encapsulation layer ENL. The optical filter layer OFL may include a light blocking member LS, color filters CF, and optical filters OF. In one embodiment, the optical filter layer OFL may further include a first overcoat layer OC1 covering the light blocking member LS, the color filters CF, and the optical filters OFL.

The light blocking member LS may be disposed above the display layer DPL (for example, above the encapsulation layer ENL covering the display layer DPL) to be located between the pixels PX and the optical sensors PS and/or at the boundary thereof. The light blocking member LS may include openings exposing at least a part of the pixels PX (for example, a light emitting unit or an emission area of each of the pixels PX). Further, the light blocking member LS may include openings exposing at least a part of the optical sensors PS (for example, a light receiving part or a light receiving area of each of the optical sensors PS).

The color filters CF may be provided in the active area AA to overlap the pixels PX. For example, the color filters CF corresponding to the colors and/or wavelength bands of lights emitted from the pixels PX may be disposed above the pixels PX.

The optical filters OF may be provided in the active area AA to overlap the optical sensors PS. For example, the optical filters OF may be disposed above the optical sensors PS. In one embodiment, the optical filters OF may be thin films having thicknesses smaller than those of the color filters CF disposed on the pixels PX. In one embodiment, the optical filters OF may be thin films having thicknesses smaller than that of the light blocking member LS. For example, each optical filter OF may have a reduced thickness to satisfy a target transmittance range of light used for light sensing in each optical sensor PS.

Each of the optical filters OF, which is a filter for transmitting light (for example, visible light) of some wavelength bands including light (for example, green light) emitted from at least some of the pixels PX, and blocking short-wavelength light (for example, short-wavelength external light belonging to the wavelength band of 300 nm or 350 nm or less including ultraviolet rays or the like) of a specific wavelength band or less, may be a metal thin film or a color filter of a specific color. The optical filter OF has a thickness smaller than those of the color filters CF disposed on the pixels PX, and thus may have a higher light transmittance to visible light or the like. For example, since the thickness of the optical filter OF is reduced, the amount (or ratio) of reflected light required for fingerprint sensing or the like absorbed by the optical filter OF may be reduced, and the amount of light received by the optical sensors PS may increase.

The window WDL may be disposed above the display panel 10 to protect the display panel 10. For example, the window WDL may be provided on the display surface of the display panel 10.

In case that the user's finger F (for example, a part of the finger F including a fingerprint region) is in contact with (or approaches) the top surface of the window WDL, the light emitted from the pixels PX of the display panel 10 may be reflected from ridges RID of the finger F and valleys VAL of the finger F disposed between the ridges RID. The portions corresponding to the ridges RID of the finger F may be in contact with the top surface of the window WDL, whereas the portions corresponding to the valleys VAL of the finger F may not be in contact with the window WDL. Accordingly, the top surface of the window WDL may be in contact with air at the portions corresponding to the valleys VAL of the finger F.

Since the refractive index of the finger F is different from the refractive index of air, the amount of light reflected from the ridges RID and the amount of light reflected from the valleys VAL may be different. Accordingly, the shape of the fingerprint formed on the finger F may be obtained based on the difference in the amount of light received by the optical sensors PS with respect to the reflected light reflected from the finger F. For example, each optical sensor PS may output an electrical signal corresponding to the amount of received light, and may sense or identify the shape of the fingerprint formed on the finger F using the electrical signals outputted from the optical sensors PS.

FIG. 4 is a cross-sectional view showing a schematic cross section of the active area AA of the display device 1 according to one embodiment, and a method for sensing a fingerprint of the finger F.

Referring to FIG. 4 in addition to FIGS. 1 to 3, the display device 1 may further include a touch sensor layer TSL. In one embodiment, the touch sensor layer TSL may be provided and/or formed inside the display panel 10. For example, the touch sensor layer TSL may be disposed between the encapsulation layer ENL and the optical filter layer OFL, and may be formed directly on the encapsulation layer ENL. The position of the touch sensor layer TSL may vary according to embodiments.

The touch sensor layer TSL may include sensing patterns TSE (for example, touch electrodes for generating an electrical signal according to a touch input) for sensing a user's touch input, and a second overcoat layer OC2 covering the sensing patterns TSE. The type, structure, and material of the sensing patterns TSE disposed on the touch sensor layer TSL may be variously changed according to embodiments.

The display device 1 may sense a user's touch input provided to the display surface side (for example, the top surface of the window WDL) using the touch sensor layer TSL. The other components of the display device 1 according to the embodiment of FIG. 4 and the method for sensing a fingerprint of the finger F using the optical sensors PS are substantially similar to or the same as those of the display device 1 according to the embodiment of FIG. 3, so that a detailed description thereof will be omitted.

FIG. 5 is a circuit diagram of the pixel PX and the optical sensor PS according to one embodiment.

FIG. 5 discloses an embodiment in which the scan lines SL connected to each pixel PX include a scan initialization line GIL, a scan control line GCL, a first scan line GWL, and a first_first scan line GWL_1. In one embodiment, the scan lines SL may further include a reset control line RSTL connected to at least one optical sensor PS.

In one embodiment, the reset control line RSTL may be connected to one of the scan initialization line GIL, the scan control line GCL, and the first_first scan line GWL_1, or may be separated from the scan initialization line GIL, the scan control line GCL, and the first_first scan line GWL_1 and receive a separate reset signal. In one embodiment, the reset signal may be sequentially applied to the optical sensors PS at least one row or in units of a block, or may be simultaneously applied to the optical sensors PS disposed in the active area AA. For example, the optical sensors PS may be sequentially reset or simultaneously reset.

In one embodiment, the optical sensor PS may be driven using at least one of the scan signals for driving the pixel PX. For example, the optical sensor PS may be driven using a first scan signal transmitted to the first scan line GWL.

Referring to FIG. 5 in addition to FIGS. 1 to 4, the pixel PX may include the light emitting element EL and the pixel circuit PXC (or a pixel driver) connected to the light emitting element EL.

The light emitting element EL may be connected between the second driving voltage line VSL to which the second power voltage ELVSS is applied and a pixel circuit PXC. The light emitting element EL, which is a light source of the pixel PX, may emit light in according to the driving current supplied from the pixel circuit PXC. As the driving current increases, the light emitting element EL may emit light with a high luminance.

In one embodiment, the light emitting element EL may be an organic light emitting diode, but is not limited thereto. For example, the light emitting element EL may be an inorganic light emitting element, a quantum dot light emitting element, or another type of light emitting element.

The pixel circuit PXC may control the light emitting timing and luminance of the light emitting element EL by controlling the driving current supplied to the light emitting element EL. The pixel circuit PXC may include a driving transistor DT, switch elements, and a capacitor Cst. In one embodiment, the switch elements may include first to sixth transistors T1, T2, T3, T4, T5, and T6.

The driving transistor DT may include a gate electrode, a first electrode, and a second electrode. One of the first electrode and the second electrode may be a source electrode and the other one may be a drain electrode. The driving transistor DT may control a drain-source current (hereinafter, referred to as “driving current”) flowing between the first electrode and the second electrode according to a voltage of the data signal applied to the gate electrode.

The first transistor T1 may include the gate electrode connected to the first scan line GWL, the first electrode connected to the data line DL, and the second electrode connected to the first electrode of the driving transistor DT. The first transistor T1 may be turned on by the first scan signal supplied to the first scan line GWL to connect the first electrode of the driving transistor DT to the data line DL. When the first transistor T1 is turned on, the voltage of the data signal supplied from the data line DL may be applied to the first electrode of the driving transistor DT.

The second transistor T2 may include the gate electrode connected to the scan control line GCL, the first electrode connected to the second electrode of the driving transistor DT, and the second electrode connected to the gate electrode (or the second node N2) of the driving transistor DT. The second transistor T2 may turned on by the scan control signal supplied to the scan control line GCL to connect the gate electrode of the driving transistor DT to the second electrode of the driving transistor DT. When the second transistor T2 is turned on, the driving transistor DT may be driven as a diode.

The third transistor T3 may include the gate electrode connected to the scan initialization line GIL, the first electrode connected to the gate electrode of the driving transistor DT, and the second electrode connected to the first initialization voltage line VIL1. The third transistor T3 may be turned on by the scan initialization signal supplied from the scan initialization line GIL to connect the gate electrode of the driving transistor DT to the first initialization voltage line VIL1. When the third transistor T3 is turned on, the first initialization voltage VINT of the first initialization voltage line VIL1 may be applied to the gate electrode of the driving transistor DT.

The fourth transistor T4 may include the gate electrode connected to the emission control line EML, the first electrode connected to the first driving voltage line VDL, and the second electrode connected to the first electrode of the driving transistor DT. The fourth transistor T4 may be turned on by the emission control signal supplied from the emission control line EML to connect the first electrode of the driving transistor DT to the first driving voltage line VDL to which the first power voltage ELVDD is applied. When the fourth transistor T4 is turned on, the first power voltage ELVDD may be applied to the first electrode of the driving transistor DT.

The fifth transistor T5 may include the gate electrode connected to the emission control line EML, the first electrode connected to the second electrode of the driving transistor DT, and the second electrode connected to the light emitting element EL. The fifth transistor T5 may be turned on by the emission control signal supplied from the emission control line EML to connect the driving transistor DT to the light emitting element EL. When both the fourth transistor T4 and the fifth transistor T5 are turned on, the driving current with a magnitude corresponding to the voltage of the gate electrode of the driving transistor DT may flow through the light emitting element EL.

The sixth transistor T6 may include the gate electrode connected to the first_first scan line GWL_1, the first electrode connected to the anode electrode of the light emitting element EL, and the second electrode connected to a second initialization voltage line VIL2. The sixth transistor T6 may turned on by a first_first scan signal supplied from the first_first scan line GWL_1 to connect the anode electrode of the light emitting element EL to a second initialization voltage line VIL2. When the sixth transistor T6 is turned on, a second initialization voltage VAINT of the second initialization voltage line VIL2 may be applied to the anode electrode of the light emitting element EL.

The capacitor Cst may be connected between the gate electrode of the driving transistor DT and the first driving voltage line VDL. The capacitor Cst may store the voltage corresponding to the voltage of the data signal applied to the gate electrode of the driving transistor DT.

In one embodiment, an active layer (for example, a semiconductor pattern including a channel region) of the driving transistor DT and each of the first to sixth transistors T1, T2, T3, T4, T5, and T6 may be formed of one of polysilicon, amorphous silicon, and an oxide semiconductor. For example, the active layer of each of the driving transistor DT, the first transistor T1, and the fourth to sixth transistors T4, T5, and T6 may be made of polysilicon. The active layer of each of the second transistor T2 and the third transistor T3 may be formed of an oxide semiconductor. In this case, the driving transistor DT, the first transistor T1, and the fourth to sixth transistors T4, T5, and T6 may be formed of P-type transistors (for example, P-type MOSFETs), and the second transistor T2 and the third transistor T3 may be formed of N-type transistors (for example, N-type MOSFETs).

The optical sensor PS may include the photoelectric conversion element PD (or a light sensing element), and the optical sensor circuit PSC (or a sensor driver) for controlling a sensing current according to the photoelectric current of the photoelectric conversion element PD.

The photoelectric conversion element PD may be connected between the optical sensor circuit PSC and the second driving voltage line VSL. The photoelectric conversion element PD may convert externally incident light into an electrical signal. In one embodiment, the photoelectric conversion element PD may be a photodiode including an anode electrode, a cathode electrode, and a photoelectric conversion layer disposed between the anode electrode and the cathode electrode. In one embodiment, the photoelectric conversion element PD may be an inorganic photodiode or a phototransistor formed of a PN type or PIN type inorganic material. Alternatively, the photoelectric conversion element PD may also be an organic photodiode including an electron donating material generating donor ions and an electron accepting material generating acceptor ions.

In case that the photoelectric conversion element PD is exposed to external light, photocharges may be generated, and the generated photocharges may be accumulated in the anode electrode of the photoelectric conversion element PD. In this case, the voltage of a first node N1 electrically connected to the anode electrode of the photoelectric conversion element PD may increase. When the second initialization voltage line VIL2 and the read-out line ROL are connected according to the turn-on of the first and third sensor transistors LT1 and LT3, a sensing voltage may be transmitted to the third node N3 between the read-out line ROL and the third sensor transistor LT3 in proportion to the voltage of the first node N1 in which the electric charges are accumulated.

The optical sensor circuit PSC may include the sensor transistors for controlling the sensing current generated by the photoelectric conversion element PD. For example, the optical sensor circuit PSC may include first to third sensor transistors LT1, LT2, and LT3.

The first sensor transistor LT1 may include the gate electrode connected to the first node N1, the first electrode connected to the second initialization voltage line VIL2, and the second electrode connected to the first electrode of the third sensor transistor LT3. The first sensor transistor LT1 may be turned on by the voltage of the first node N1 to connect the second initialization voltage line VIL2 to the first electrode of the third sensor transistor LT3. The first sensor transistor LT1 may be a source follower amplifier that generates a source-drain current in proportion to the amount of electric charges of the first node N1 inputted to the gate electrode thereof. FIG. 5 discloses an embodiment in which the first electrode of the first sensor transistor LT1 is connected to the second initialization voltage line VIL2, but the embodiments are not limited thereto. For example, the first electrode of the first sensor transistor LT1 may be connected to the first driving voltage line VDL or the first initialization voltage line VIL1.

The second sensor transistor LT2 may include the gate electrode connected to the reset control line RSTL, the first electrode connected to the reset voltage line VRL, and the second electrode connected to the first node N1. The second sensor transistor LT2 may be turned on by the reset control signal supplied to the reset control line RSTL to connect the reset voltage line VRL to which the reset voltage Vrst is applied to the first node N1. When the second sensor transistor LT2 is turned on, the voltage of the first node N1 may be initialized by the reset voltage Vrst.

The third sensor transistor LT3 may include the gate electrode connected to the first scan line GWL, the first electrode connected to the second electrode of the first sensor transistor LT1, and the second electrode connected to the read-out line ROL. The third sensor transistor LT3 may be turned on by the first scan signal supplied to the first scan line GWL to connect the second electrode of the first sensor transistor LT1 and the read-out line ROL. When the third sensor transistor LT3 is turned on, the electrical signal corresponding to the photoelectric current flowing through the optical sensor PS may be transmitted to the read-out IC 40 through the read-out line ROL.

In one embodiment, the active layer of each of the first to third sensor transistors LT1, LT2, and LT3 may be formed of one of polysilicon, amorphous silicon, and an oxide semiconductor. For example, the active layer of each of the first sensor transistor LT1 and the third sensor transistor LT3 may be made of polysilicon, and the active layer of the second sensor transistor LT2 may be made of an oxide semiconductor. In this case, the first sensor transistor LT1 and the third sensor transistor LT3 may be formed of P-type transistors (for example, P-type MOSFETs), and the second sensor transistor LT2 may be formed of an N-type transistor (for example, N-type MOSFET).

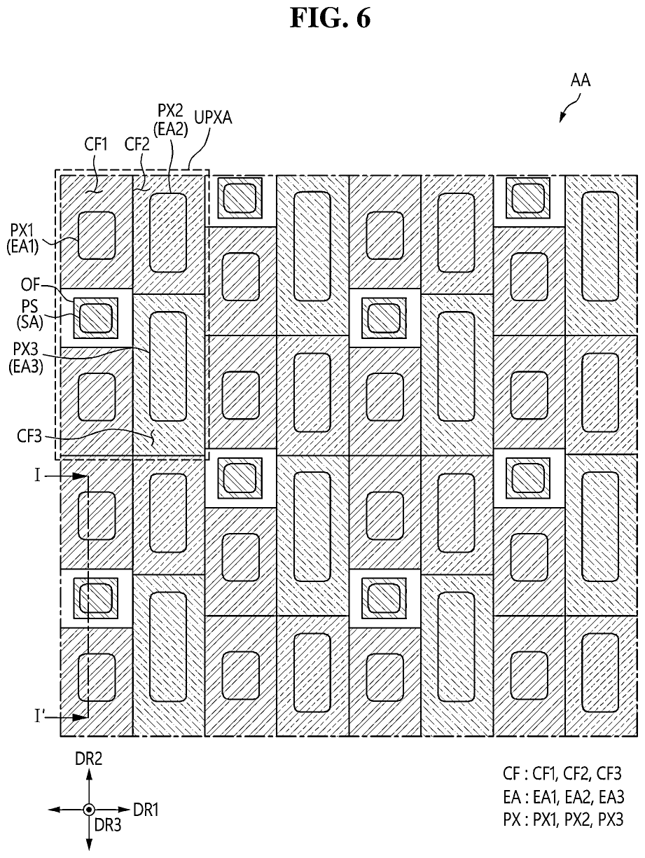

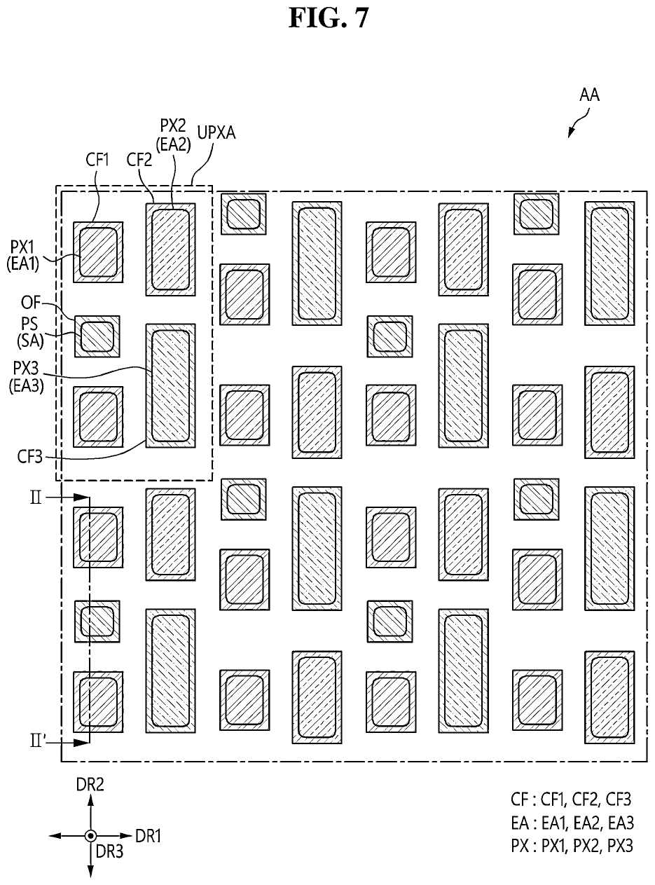

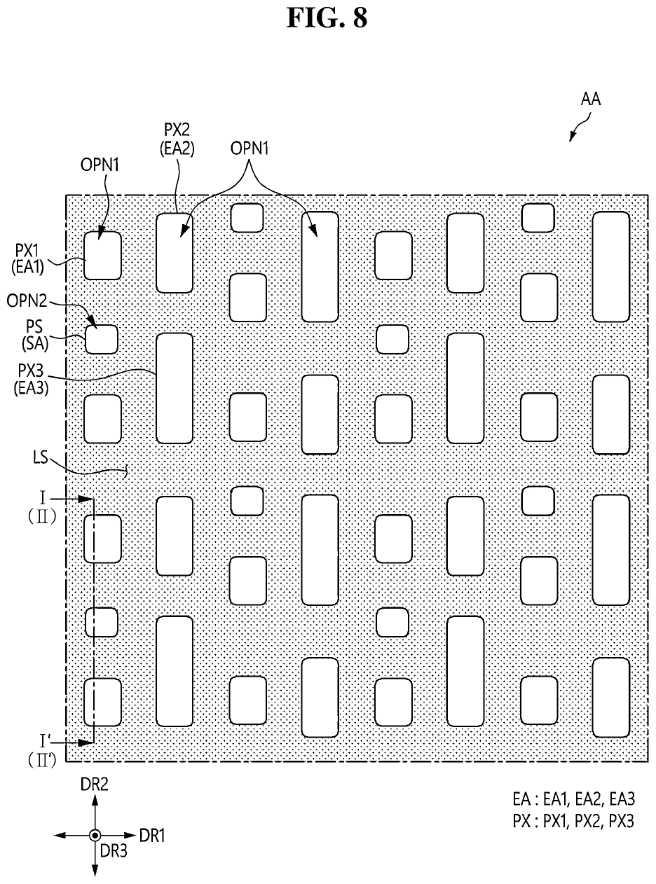

FIG. 6 is a plan view showing the arrangement structure of the pixels PX, the optical sensors PS, the color filters CF and the optical filters OF according to one embodiment. FIG. 7 is a plan view showing the arrangement structure of the pixels PX, the optical sensors PS, the color filters CF and the optical filters OF according to one embodiment. For example, FIGS. 6 and 7 show different embodiments in relation to the color filters CF disposed on pixels PX. FIG. 8 is a plan view showing the pixels PX, the optical sensors PS, and the light blocking member LS according to one embodiment. FIGS. 6 to 8 illustrate the pixels PS, the optical sensors PS, the color filters CF, the optical filters OF, and the light blocking member LS disposed in a part of the active area AA of the display device 1.

Referring to FIGS. 6 to 8 in addition to FIGS. 1 to 5, the pixels PX may include first color pixels (also referred to as “first pixels”) PX1 emitting light of a first color, second color pixels (also referred to as “second pixels”) PX2 emitting light of a second color, and third color pixels (also referred to as “third pixels”) PX3 emitting light of a third color. In one embodiment, the first color pixels PX1 may be green pixels emitting green light, the second color pixels PX2 may be red pixels emitting red light, and the third color pixels PX3 may be blue pixels emitting blue light. However, the embodiments are not limited thereto, and the type and configuration of the pixels PX and the color of light emitted from each pixel PX may vary according to embodiments.

In one embodiment, at least one first color pixel PX1, at least one second color pixel PX2, and at least one third color pixel PX3 that are disposed adjacent to each other in one unit pixel area UPXA may constitute one unit pixel. For example, two first color pixels PX1, one second color pixel PX2, and one third color pixel PX3 that are disposed in each unit pixel area UPXA may constitute one unit pixel. Each unit pixel may be defined as minimum pixels PX for displaying white light. Various colors may be expressed by adjusting the light emitting ratio of the pixels PX included in each unit pixel.

In one embodiment, the first color pixels PX1 may be arranged in even numbered pixel columns, and the second color pixels PX2 and the third color pixels PX3 may be arranged in odd numbered pixel columns. The optical sensors PS may be disposed in the even numbered pixel columns or in the odd numbered pixel columns, and may be disposed with a resolution that is the same as or different from that of the pixels PX disposed in each pixel column.

In one embodiment, the optical sensors PS may be disposed in the odd numbered pixel columns where the first color pixels PX1 are disposed. For example, the optical sensors PS may be disposed in each odd numbered pixel column where the first color pixels PX1 are disposed. In one embodiment, the sensing area SA of each of the optical sensors PS may be disposed adjacent to at least one first emission area EA1, and each optical sensor PS may generate a sensing signal using the light emitted from the first emission area EA1. For example, each optical sensor PS may be disposed between the first emission areas EA1 of at least two first color pixels PX1 arranged in the pixel column where the optical sensor PS is located, and may operate using light emitted from adjacent first color pixels PX1 as a light source. The shape, arrangement structure, resolution, and the like of the pixels PX and the optical sensors PS are not limited to the embodiment illustrated in FIGS. 6 to 8, and may be variously changed according to embodiments.

Each of the pixels PX may include the respective emission areas EA (or light emitting units including the respective light emitting elements EL). For example, the first color pixel PX1 may include a first emission area EA1 emitting first light of a first color (for example, green light with a peak wavelength in a range of about 510 nm to 550 nm), and the second color pixel PX2 may include a second emission area EA2 emitting second light of a second color (for example, red light with a peak wavelength in a range of about 610 nm to 650 nm). The third color pixel PX3 may include a third emission area EA3 emitting third light of a third color (for example, blue light with a peak wavelength in a range of about 440 nm to 480 nm).

For simplicity, in FIGS. 6 to 8, the location of the corresponding pixel PX is displayed with respect to the emission area EA of each pixel PX, but the pixel PX may have an area greater than that of the emission area EA. For example, the pixel area where each pixel PX is disposed or formed may include a pixel circuit area where the pixel circuit PXC of the corresponding pixel PX is formed and the emission area EA where the light emitting element EL of the corresponding pixel PX or the like is formed. In one embodiment, the first color pixels PX1, the second color pixels PX2, and/or the third color pixels PX3 may include the emission areas EA having different sizes (for example, different areas) according to the luminous efficiency or white balance of the first color pixels PX1, the second color pixels PX2, and/or the third color pixels PX3, but embodiments are not limited thereto.

The color filters CF may be disposed on the emission areas EA (or the light emitting units including the respective light emitting elements EL) of the pixels PX and peripheral areas thereof. For example, a first color filter CF1 (for example, a color filter of the first color) for selectively transmitting light of the first color may be disposed in the first emission area EA1 of the first color pixel PX1, and a second color filter CF2 (for example, a color filter of the second color) for selectively transmitting light of the second color may be disposed in the second emission area EA2 of the second color pixel PX2. A third color filter CF3 (for example, a color filter of the third color) for selectively transmitting light of the third color may be disposed in the third emission area EA3 of the third color pixel PX3. In one embodiment, the first color filter CF1, the second color filter CF2, and the third color filter CF3 may be a green color filter, a red color filter, and a blue color filter, respectively.

The color filters CF may be entirely disposed in the emission areas EA to cover at least the emission areas EA. For example, the color filters CF may be disposed or provided above the pixels PX to completely cover the emission areas EA of the pixels PX.

In one embodiment, as shown in FIG. 6, the color filters CF may be formed to be wider enough to be in contact with the color filters CF adjacent in the first direction DR1 and/or the second direction DR2 or very close to the adjacent color filters CF. In another embodiment, as shown in FIG. 7, the color filters CF may have a smaller area, and may be spaced apart from each other by a larger distance. For example, adjacent color filters CF may be spaced apart from each other by a distance corresponding to the width of the top surface of the light blocking member LS interposed therebetween.

The optical sensors PS may be disposed in an area for sensing light. For example, when it is desired to sense fingerprints or the like using the optical sensors PS in the active area AA, the optical sensors PS may be disposed in the active area AA together with the pixels PX. For example, the optical sensors PS may be disposed between the pixels PX. The optical sensors PS may be disposed uniformly or non-uniformly across the active area AA, or may be disposed only in a part of the active area AA. In one embodiment, the optical sensors PS may be disposed between the third color pixels PX3 in each pixel column where the third color pixels PX3 are disposed. However, the embodiments are not limited thereto, and the arrangement structure, location, number, and/or resolution of the optical sensors PS may be variously changed according to embodiments.

The optical sensors PS may include sensing areas SA. The photoelectric conversion element PD may be disposed in the sensing area SA of each of the optical sensors PS.

Each of the sensing areas SA may include a light receiving part where the optical filter OF is disposed. For example, the optical filter OF capable of transmitting light of a wavelength band corresponding to the light of the first color emitted from the first color pixel PX1, the light of the second color emitted from the second color pixel PX2, and/or the light of the third color emitted from the third color pixel PX3 may be disposed in the light receiving part (or light receiving portion) of each of the sensing areas SA. For example, the optical filter OF capable of transmitting visible light including the light of the first color, the light of the second color, and the light of the third color, or the optical filter OF capable of selectively transmitting any one of the light of the first color, the light of the second color, and the light of the third color may be disposed in each sensing area SA.

In one embodiment, the light receiving part of the optical sensor PS may be an area corresponding to the sensing area SA of the optical sensor PS. For example, the light receiving part of the optical sensor PS, which is an area where the photoelectric conversion element PD is exposed by the second opening OPN2 of the light blocking member LS, may be an area that is substantially the same as the sensing area SA, or may be an area including the sensing area SA. Each of the optical sensors PS may output a sensing signal according to the amount of received light (for example, the amount of light incident on each photoelectric conversion element PD) through the light receiving part.

In one embodiment, the optical filter OF may be disposed on the light receiving part of each of the optical sensors PS. For example, in the sensing area SA (or a sensing unit including the photoelectric conversion element PD) of each of the optical sensors PS, the optical filter OF may be disposed on each optical sensor PS. In one embodiment, each optical filter OF may entirely cover the light receiving part of the optical sensor PS in each sensing area SA. In one embodiment, the optical filters OF may have areas larger than that of each sensing area SA, and may be spaced apart from the color filters CF disposed adjacent to each other with the light blocking member LS interposed therebetween.

In one embodiment, each optical filter OF may be a metal thin film or a color filter (for example, the color filter for selectively transmitting the light of the first color similar to the first color filter CF1, which is the first color filter having a thickness smaller than that of the first color filter CF1) capable of transmitting at least the light of the first color, and each optical sensor PS may operate using the light emitted from at least one adjacent first color pixel PX1 as a light source.

In one embodiment, the optical sensors PS may constitute a fingerprint sensor provided in the active area AA. For example, each of the optical sensors PS may be a sensing pixel of a fingerprint sensor.

The light blocking member LS may be disposed in the active area AA, and may be located in a non-emission area and/or a non-sensing area corresponding to the peripheries and/or edges of the pixels PX and the optical sensors PS. The light blocking member LS may include openings exposing the emission areas EA of the pixels PX and the sensing areas SA of the optical sensors PS, and may surround the emission areas EA and the sensing areas SA. For example, the light blocking member LS may include first openings OPN1 corresponding to the emission areas EA and second openings OPN2 corresponding to the sensing areas SA, and may surround the emission areas EA and the sensing areas SA.

The first openings OPN1 may expose at least a part of the light emitting elements EL disposed in the emission areas EA. The second openings OPN2 may expose at least a part of the photoelectric conversion elements PD disposed in the sensing areas SA.

In one embodiment, each of the second openings OPN2 may define the light receiving part of each of the optical sensors PS. For example, light may be incident on the optical sensors PS through the second openings OPN2.

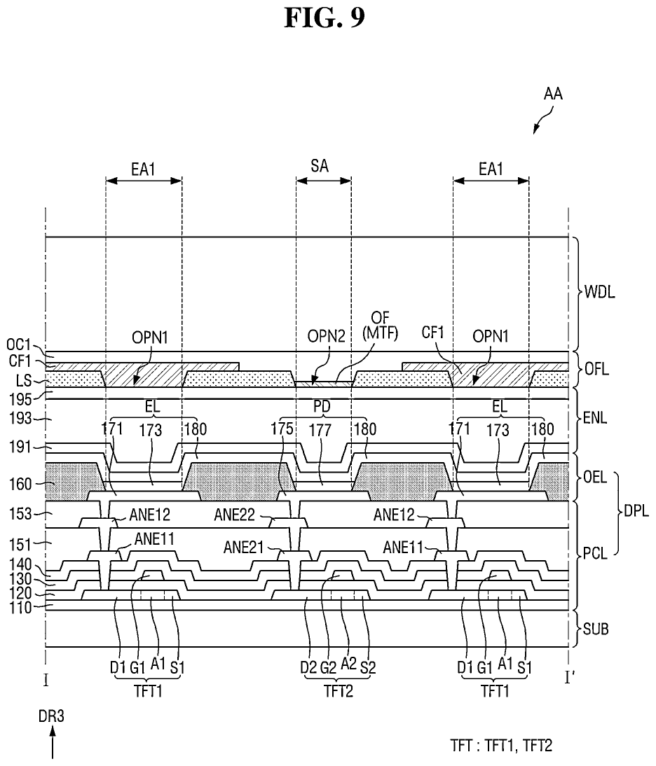

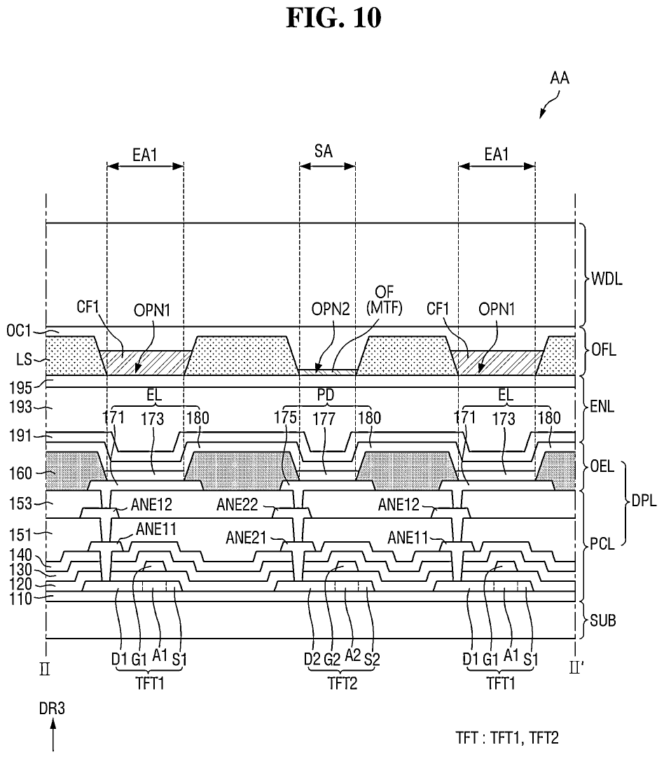

FIG. 9 is a cross-sectional view showing an example of a cross section of the display device 1 taken along line I-I′ of FIGS. 6 and 8. FIG. 10 is a cross-sectional view showing an example of a cross section of the display device 1 taken along line II-II′ of FIGS. 7 and 8. For example, FIGS. 9 and 10 show cross sections according to different embodiments in relation to the optical filter layer OFL provided in the active area AA of the display device 1.

Referring to FIGS. 9 and 10 in addition to FIGS. 1 to 8, the substrate SUB, which is a base member (or a base layer) of the display panel 10, may be rigid or flexible. In one embodiment, the substrate SUB may be one of a glass substrate, a quartz substrate, a glass ceramic substrate, a film substrate including a high molecular organic material, and a plastic substrate, but is not limited thereto.

The active area AA and the non-active area NA may be defined on the substrate SUB. The pixels PX and the optical sensors PS may be located in the active area AA on the substrate SUB. For example, the active area AA may include each pixel area including each emission area EA, and each optical sensor area including each sensing area SA.

A panel circuit layer PCL (for example, a pixel circuit layer or a thin film transistor layer) may be disposed on the substrate SUB. The panel circuit layer PCL may include a barrier layer 110 (or a buffer layer) and circuit elements and/or signal lines disposed on the barrier layer 110. For example, the panel circuit layer PCL may include a first thin film transistor TFT1 (also referred to as “pixel transistor”) provided to each pixel PX, and a second thin film transistor TFT2 (also referred to as “sensor transistor”) provided to each optical sensor PS. For example, the first thin film transistor TFT1 may be the driving transistor DT or one of the first to sixth transistors T1 to T6 of FIG. 5, and the second thin film transistor TFT2 may be one of the first to third sensor transistors LT1 to LT3 of FIG. 5. The panel circuit layer PCL may further include the other circuit elements (for example, other transistors and capacitors Cst) included in each pixel circuit PXC, the other circuit elements (for example, other sensor transistors) included in each optical sensor circuit PSC, and signal lines connected to the pixels PX and the optical sensors PS.

The barrier layer 110 may be disposed on the substrate SUB. The barrier layer 110 may include an inorganic insulating material including silicon nitride, silicon oxide, silicon oxynitride or the like, or another insulating material.

An active layer (or a semiconductor pattern) of each of the thin film transistors TFT may be disposed on the barrier layer 110. The active layer may include polycrystalline silicon, monocrystalline silicon, low-temperature polycrystalline silicon, amorphous silicon, an oxide semiconductor, or other semiconductor materials.

The active layer of the first thin film transistor TFT1 may include a first channel region A1, and a first source region S1 and a first drain region D1 that are doped with impurities and have conductivity. The first channel region A1 may overlap a first gate electrode G1 in the third direction DR3 that is the thickness direction of the substrate SUB. The first source region S1 and the first drain region D1 may not overlap the first gate electrode G1.

The active layer of the second thin film transistor TFT2 may include a second channel region A2, and a second source region S2 and a second drain region D2 that are doped with impurities and have conductivity. The first channel region A1 may overlap a second gate electrode G2 in the third direction DR3 that is the thickness direction of the substrate SUB. The second source region S2 and the second drain region D2 may not overlap the second gate electrode G2.

In one embodiment, the first and second thin film transistors TFT1 and TFT2 may be disposed on substantially the same layer above the substrate SUB. Further, at least a part of the first thin film transistor TFT1 and at least a part of the second thin film transistor TFT2 may be formed simultaneously by the same process. Accordingly, the thickness of the display device 1 including the pixels PX and the optical sensors PS may be reduced or minimized, and the manufacturing process of the display device 1 may become efficient and/or simplified.

A first insulating layer 120 (for example, a gate insulating layer) may be disposed on the active layers of the thin film transistors TFT. In one embodiment, the first insulating layer 120 may include at least one inorganic insulating layer including an inorganic insulating material.

The gate electrode of each of the thin film transistors TFT may be disposed on the first insulating layer 120. For example, the first gate electrode G1 of the first thin film transistor TFT1 and the second gate electrode G2 of the second thin film transistor TFT2 may be disposed on the first insulating layer 120. In one embodiment, the gate electrodes may include any one of molybdenum (Mo), aluminum (Al), chromium (Cr), gold (Au), titanium (Ti), nickel (Ni), neodymium (Nd) and copper (Cu) or an alloy thereof. The gate electrodes may also include other conductive materials. In one embodiment, the first electrode of the capacitor Cst of FIG. 5 and/or at least one signal line may be further disposed on the first insulating layer 120.

A second insulating layer 130 (for example, a first interlayer insulating layer) may be disposed on the gate electrodes of the thin film transistors TFT. In one embodiment, the second insulating layer 130 may include at least one inorganic insulating layer including an inorganic insulating material. In one embodiment, the second electrode of the capacitor Cst of FIG. 5 and/or at least one signal line may be disposed on the second insulating layer 130.

A third insulating layer 140 (for example, a second interlayer insulating layer) may be disposed on the second insulating layer 130, the second electrode of the capacitor Cst, and/or at least one signal line. In one embodiment, the third insulating layer 140 may include at least one inorganic insulating layer including an inorganic insulating material. In another embodiment, the second electrode of the capacitor Cst may be disposed on the same layer as first anode connection electrodes ANE11 and ANE21, and the third insulating layer 140 may be omitted.

The first anode connection electrodes ANE11 and ANE21 (or first bridge patterns) may be disposed on the third insulating layer 140. The first anode connection electrodes ANE11 and ANE21 may be connected to the drain regions D1 and D2 of the respective thin film transistors TFT through respective contact holes formed through the first insulating layer 120, the second insulating layer 130, and the third insulating layer 140. Although FIGS. 9 and 10 show an embodiment in which the first anode connection electrodes ANE11 and ANE21 are connected to the first drain region D1 and the second drain region D2, respectively, the embodiments are not limited thereto. For example, depending on the conductivity type (for example, N-type or P-type) of the first thin film transistor TFT1 and the second thin film transistor TFT2, each of the first anode connection electrodes ANE11 and ANE21 may be connected to one of the first source region S1 and the first drain region D1, or one of the second source region S2 and the second drain region D2. In one embodiment, the first anode connection electrodes ANE11 and ANE21 may include any one of molybdenum (Mo), aluminum (Al), chromium (Cr), gold (Au), titanium (Ti), nickel (Ni), neodymium (Nd) and copper (Cu) or an alloy thereof, but are not limited thereto.

A fourth insulating layer 151 (for example, a first planarization layer) may be disposed on the first anode connection electrodes ANE11 and ANE21. In one embodiment, the fourth insulating layer 151 may include at least one organic insulating layer containing acryl resin, epoxy resin, phenolic resin, polyamide resin, polyimide resin, or other organic insulating materials. The fourth insulating layer 151 may flatten a stepped portion formed by the thin film transistors TFT.

Second anode connection electrodes ANE12 and ANE22 (or second bridge patterns) may be disposed on the fourth insulating layer 151. The second anode connection electrodes ANE12 and ANE22 may be connected to the first anode connection electrodes ANE11 and ANE21 through contact holes formed through the fourth insulating layer 151, respectively. In one embodiment, the second anode connection electrodes ANE12 and ANE22 may include the same material as the first anode connection electrodes ANE11 and ANE21.

A fifth insulating layer 153 (for example, a second planarization layer) may be disposed on the second anode connection electrodes ANE12 and ANE22. In one embodiment, the fifth insulating layer 153 may include the same material as the fourth insulating layer 151.

In one embodiment, the second anode connection electrodes ANE12 and ANE22 and/or the fifth insulating layer 153 may be omitted. For example, the first anode connection electrodes ANE11 and ANE21 may be directly connected to the light emitting elements EL and the photoelectric conversion elements PD.

An optical element layer OEL may be disposed on the fifth insulating layer 153. The optical element layer OEL may include the light emitting element EL of each of the pixels PX, the photoelectric conversion element PD of each of the optical sensors PS, and a bank 160. Each light emitting element EL may be located in each emission area EA (for example, the emission area EA of the corresponding pixel PX), and each photoelectric conversion element PD may be located in each sensing area SA (for example, the sensing area SA of the corresponding optical sensor PS). The bank 160 may define or partition each emission area EA and each sensing area SA.

Each light emitting element EL may include a pixel electrode 171 (for example, an anode electrode), a light emitting layer 173, and a common electrode 180 (for example, a cathode electrode). Each photoelectric conversion element PD may include a first electrode 175 (for example, an anode electrode), a photoelectric conversion layer 177, and the common electrode 180. In one embodiment, the light emitting elements EL and the photoelectric conversion elements PD may share the common electrode 180.

The pixel electrode 171 of the light emitting element EL may be disposed on the fifth insulating layer 153. The pixel electrode 171 may be provided for each pixel PX. For example, the pixel electrode 171 of the light emitting element EL may be disposed in the emission area EA of the pixel PX. The pixel electrode 171 may be connected to the second anode connection electrode ANE12 through the contact hole formed through the fifth insulating layer 153.

In one embodiment, the pixel electrode 171 of the light emitting element EL may have a single-layer structure of molybdenum (Mo), titanium (Ti), copper (Cu) or aluminum (Al), or may have a stacked-layer structure, for example, a multilayer structure of ITO/Mg, ITO/MgF, ITO/Ag, and ITO/Ag/ITO including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

Further, the first electrode 175 of the photoelectric conversion element PD may be disposed on the fifth insulating layer 153. The first electrode 175 may be provided for each optical sensor PS. For example, the first electrode 175 of the photoelectric conversion element PD may be disposed in the sensing area SA of the optical sensor PS. The first electrode 175 may be connected to the second anode connection electrode ANE22 of the corresponding optical sensor PS through the contact hole formed through the fifth insulating layer 153.

In one embodiment, the first electrode 175 of the photoelectric conversion element PD may have a single-layer structure of molybdenum (Mo), titanium (Ti), copper (Cu), or aluminum (Al), or may have a multilayer structure of ITO/Mg, ITO/MgF, ITO/Ag, and ITO/Ag/ITO. However, the embodiments are not limited thereto, and the material and/or structure of the first electrode 175 of the photoelectric conversion element PD may vary according to embodiments.

The bank 160 may be disposed on the pixel electrode 171 and the first electrode 175. The bank 160 may be formed in the region (for example, the upper portion of the edge of the pixel electrode 171) overlapping the pixel electrode 171, and may include an opening exposing a part of the pixel electrode 171. The region where the exposed pixel electrode 171 and the light emitting layer 173 overlap (or, the region including the same) may be defined as the emission area EA of each pixel PX.

Further, the bank 160 may be formed in the region (for example, the upper portion of the edge of the first electrode 175) overlapping the first electrode 175, and may include an opening exposing the first electrode 175. The opening exposing the first electrode 175 may provide a space in which the photoelectric conversion layer 177 of each optical sensor PS is formed. The area where the exposed first electrode 175 and the photoelectric conversion layer 177 overlap (or the area including the same) may be defined as the sensing area SA (or the light sensing area) of each optical sensor PS. For example, the bank 160 may be disposed around the emission areas EA and the sensing areas SA to surround each of the emission areas EA and the sensing areas SA.

In one embodiment, the bank 160 may include an organic insulating material selected from the group consisting of acrylic resin, epoxy resin, phenolic resin, polyamide resin, polyimide resin, unsaturated polyester resin, polyphenylene ether resin, polyphenylenesulfide resin and benzocyclobutene (BCB). Alternatively, the bank 160 may include an inorganic material such as silicon nitride. The material of the bank 160 may vary according to embodiments.

The light emitting layer 173 may be disposed on the pixel electrode 171 of the light emitting element EL exposed by the opening of the bank 160. The light emitting layer 173 may include a high molecular material or a low molecular material. Light emitted from the light emitting layer 173 may contribute to image display. In one embodiment, the light emitting layer 173 may be provided for each pixel PX, and the light emitting layer 173 of each pixel PX may emit visible light of a color corresponding to the corresponding pixel PX. In another embodiment, the light emitting layer 173 may be a common layer shared by the pixels PX of different colors, and a wavelength conversion layer corresponding to a color (or a wavelength band) of light to be emitted from each of the pixels PX may be disposed in the emission areas EA of at least some of the pixels PX.

In case that the light emitting layer 173 is formed of an organic material, a hole injection layer and/or a hole transport layer may be disposed under each light emitting layer 173, and an electron injection layer and/or an electron transport layer may be stacked on each light emitting layer 173. They may be a single layer or a multilayer formed of an organic material.

The photoelectric conversion layer 177 may be disposed on the first electrode 175 of the photoelectric conversion element PD exposed by the opening of the bank 160. The photoelectric conversion layer 177 may generate photocharges corresponding to (for example, in proportion to) incident light. Electric charges generated and accumulated in the photoelectric conversion layer 177 may be converted into electrical signals required for light sensing (e.g., fingerprint sensing).

The photoelectric conversion layer 177 may include an electron donating material and an electron accepting material. The electron donating material may generate donor ions in response to light, and the electron accepting material may generate acceptor ions in response to light.

In one embodiment, when the photoelectric conversion layer 177 is formed of an organic material, the electron donating material may include a compound such as subphthalocyanine (SubPc) or dibutylphosphate (DBP), but is not limited thereto. The electron accepting material may include a compound such as fullerene, a fullerene derivative, or perylene diimide, but is not limited thereto. In another embodiment, when the photoelectric conversion layer 177 is formed of an inorganic material, the photoelectric conversion element PD may be a PN type or PIN type phototransistor.

In case that the photoelectric conversion layer 177 is formed of an organic material, a hole injection layer and/or a hole transport layer may be disposed under each photoelectric conversion layer 177, and an electron injection layer and/or an electron transport layer may be disposed above each photoelectric conversion layer 177. They may be a single layer or a multilayer formed of an organic material.

In one embodiment, the sensing area SA may be an area that receives light having the same wavelength as that of light generated from the emission area EA of an adjacent pixel PX while using the light as a light source. For example, the sensing area SA may receive light having the same wavelength as that of light (for example, green light) generated from the first emission area EA1 of at least one adjacent first color pixel PX1 while using the light as a light source.

The common electrode 180 may be disposed on the light emitting layer 173, the photoelectric conversion layer 177, and the bank 160. In one embodiment, the common electrode 180 may be disposed across the pixels PX and the optical sensors PS to cover the light emitting layer 173, the photoelectric conversion layer 177, and the bank 160. In one embodiment, the common electrode 180 may include a conductive material having a low work function, for example, Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg, etc.). Alternatively, the common electrode 180 may include a transparent metal oxide, for example, indium-tin-oxide (ITO), indium-zinc-oxide (IZO), zinc oxide (ZnO) or the like.

In one embodiment, the light emitting elements EL and the photoelectric conversion elements PD may be disposed substantially on the same layer above the substrate SUB. For example, the light emitting elements EL and the photoelectric conversion elements PD may be disposed on an insulating layer (for example, the fifth insulating layer 153) disposed on the uppermost portion of the panel circuit layer PCL. Further, at least a part of the light emitting elements EL and at least a part of the photoelectric conversion elements PD may be formed simultaneously by the same process. Accordingly, the thickness of the display device 1 including the pixels PX and the optical sensors PS may be reduced or minimized, and the manufacturing process of the display device 1 may become efficient and/or simplified.

The encapsulation layer ENL may be disposed on the optical element layer OEL. In one embodiment, the encapsulation layer ENL may include at least one inorganic layer and one organic layer to protect each of the light emitting layer 173 and the photoelectric conversion layer 177 from permeation of oxygen or moisture or foreign matter such as dust. For example, the encapsulation layer ENL may have a structure in which a first inorganic layer 191, an organic layer 193, and a second inorganic layer 195 are sequentially stacked. In one embodiment, the first inorganic layer 191 and the second inorganic layer 195 may include silicon nitride, silicon oxynitride, silicon oxide, titanium oxide, aluminum oxide, or other inorganic materials. In one embodiment, the organic layer 193 may include acryl resin, epoxy resin, phenolic resin, polyamide resin, polyimide resin, or other organic materials.

The optical filter layer OFL may be disposed on the encapsulation layer ENL. The optical filter layer OFL may include the light blocking member LS, the color filters CF, the optical filters OF, and the first overcoat layer OC1.

The light blocking member LS may be disposed on the encapsulation layer ENL protecting the optical element layer OEL. The light blocking member LS may be disposed in the active area AA to be located between the emission areas EA and/or the sensing areas SA, and may surround the emission areas EA and the sensing areas SA.

The light blocking member LS may include the first openings OPN1 disposed in areas corresponding to the emission areas EA of the pixels PX and the second openings OPN2 disposed in areas corresponding to the sensing areas SA of the optical sensors PS. Each first opening OPN1 may be located in an area corresponding to each emission area EA. Each second opening OPN2 may be located in an area corresponding to each sensing area SA. The second opening OPN2 of the light blocking member LS may correspond to the light receiving part of the photoelectric conversion element PD corresponding thereto. For example, each second opening OPN2 may correspond to the light receiving part of the photoelectric conversion element PD.

Although FIGS. 9 and 10 show embodiments in which the first openings OPN1 and the second openings OPN2 of the light blocking member LS have substantially the same width and/or area as those of the openings of the bank 160 and disposed in areas corresponding to the openings of the bank 160, the embodiments are not limited thereto. For example, the size (e.g., area) and/or shape of the first openings OPN1 and/or the second openings OPN2 of the light blocking member LS may be changed in consideration of the light emission characteristics or viewing angles of the pixels PX, the light receiving rates of the optical sensors PS, and the like. For example, each of the first openings OPN1 and the second openings OPN2 in the light blocking member LS may have a width and a length greater than openings in the bank 160 corresponding to the emission areas EA and/or the sensing areas SA.

The light blocking member LS may be formed of a material capable of absorbing and/or blocking light. For example, the light blocking member LS may be formed of a photosensitive resin including an organic black pigment or an inorganic black pigment such as carbon black or the like.

In one embodiment, instead of arranging a separate light blocking member LS, at least two color filters CF adjacent to each other may overlap to replace the light blocking member LS. For example, among the first color filter CF1, the second color filter CF2, and the third color filter CF3, at least two color filters CF may be arranged at the position where the light blocking member LS of FIGS. 9 and 10 is disposed to block the transmission of light.

The color filters CF may include the first color filters CF1 for selectively transmitting light of the first color, the second color filters CF2 for selectively transmitting light of the second color, and third color filters CF3 for selectively transmitting light of the third color. Each color filter CF may be entirely disposed in the first opening OPN1 of the light blocking member LS corresponding to each emission area EA, and may control each emission area EA to emit light of a specific color.

The first color filters CF1 may be located in the first emission areas EA1 to be disposed on the light emitting elements EL of the first color pixels PX1. For example, the first color filters CF1 may be located in the first openings OPN1 (for example, the first openings OPN1 of a first group corresponding to the first color pixels PX1) of the light blocking member LS. Each first color filter CF1 may overlap the light emitting element EL corresponding thereto.

The second color filters CF2 may be located in the second emission areas EA2 to be disposed on the light emitting elements EL of the second color pixels PX2. For example, the second color filters CF2 may be located in the first openings OPN1 (for example, the first openings OPN1 of a second group corresponding to the second color pixels PX2) of the light blocking member LS. Each second color filter CF2 may overlap the light emitting element EL corresponding thereto.

The third color filters CF3 may be located in the third emission areas EA3 to be disposed on the light emitting elements EL of the third color pixels PX3. For example, the third color filters CF3 may be located in the first openings OPN1 (for example, the first openings OPN1 of a third group corresponding to the third color pixels PX3) of the light blocking member LS. Each third color filter CF3 may overlap the light emitting element EL corresponding thereto.

In one embodiment, the light blocking member LS may be formed to have a height lower than those of the color filters CF, and a part of each of the color filters CF may be disposed on a part of the light blocking member LS. For example, as shown in FIG. 9, the edge of the first color filter CF1 may be disposed on the light blocking member LS.

In one embodiment, the light blocking member LS may be formed to have a height higher than those of the color filters CF, and each of the color filters CF may be completely surrounded by the light blocking member LS. For example, as shown in FIG. 10, the first color filter CF1 may be located in the first opening OPN1 of the light blocking member LS, and may be surrounded by the light blocking member LS. In one embodiment, after the area where each color filter CF and each optical filter OF will be formed is partitioned by forming the light blocking member LS, the color filters CF may be formed by an inkjet printing method or the like.

The optical filters OF may be located in the sensing areas SA to be disposed on the photoelectric conversion elements PD of the optical sensors PS. For example, the optical filters OF may be located in the second openings OPN2 of the light blocking member LS. Each optical filter OF may overlap the photoelectric conversion element PD corresponding thereto. In one embodiment, the optical filters OF may be formed to have substantially the same material, structure, and/or thickness, but the present disclosure is not limited thereto.

In one embodiment, the optical filters OF may be disposed on substantially the same layer as the color filters CF above the optical element layer OEL. For example, the color filters CF and the optical filters OF may be located on the encapsulation layer ENL and may be disposed substantially on the same layer. Accordingly, even when the optical filters OF are disposed or formed separately from the color filters CF, an increase in the thickness of the display device 1 may be prevented or minimized.

In one embodiment, the optical filters OF may selectively transmit light of a specific wavelength band and/or color. For example, each optical filter OF may include or may be a metal thin film MTF transmitting light corresponding to the wavelength band of light emitted from at least one emission area EA. For example, the optical filter OF may include the metal thin film MTF transmitting light (for example, visual light) of some wavelength bands including light emitted from at least one light emitting element EL located in the first emission area EA1, the second emission area EA2, and/or the third emission area EA3. Accordingly, a sensing signal may be outputted from the optical sensor PS using light emitted from the at least one emission area EA. For example, each optical filter OF may include the metal thin film MTF transmitting light of the first color emitted from at least the first emission area EA1, and may cause at least one first pixel PX1 to emit light while the sensing mode is being executed and use it as the light source of the optical sensor PS.

In one embodiment, each optical filter OF may include or may be the metal thin film MTF absorbing and/or blocking light of a short wavelength lower than a specific wavelength band. For example, the metal thin film MTF may transmit light (for example, visible light) of some wavelength bands including light emitted from the light emitting element EL, and may absorb and/or block short-wavelength light (for example, short-wavelength external light belonging to a wavelength band of approximately 300 nm or less a wavelength band of approximately 350 nm or less) of a short wavelength lower than a specific wavelength band.

In one embodiment, the optical filter OF may be a thin film having a thickness smaller than that of the color filter CF disposed on the light emitting element EL. For example, the optical filter OF may include the metal thin film MTF having a thickness of approximately 10 nm or less. In one embodiment, the metal thin film MTF may include at least one metal selected among copper (Cu), gold (Au), silver (Ag), nickel (Ni), titanium (Ti), vanadium (V), and aluminum (Al), an alloy thereof, or other metals. The material and the thickness of the optical filter OF may be appropriately set in consideration of the light transmittance (or the light absorption rate) according to the material and the thickness of the metal thin film MTF constituting the optical filter OF. For example, the metal thin film MTF may have a material and a thickness selected according to the wavelength band of light to be transmitted or blocked using the metal thin film MTF, and the transmittance (or the absorption rate) for a target wavelength band of light. In one embodiment, the metal thin film MTF may be formed by a deposition (for example, thermal deposition) process, but the formation method of the metal thin film MTF is not limited thereto.

In one embodiment, each optical filter OF may be entirely disposed in each second opening OPN2. For example, each optical filter OF may be entirely disposed on the light receiving part of the photoelectric conversion element PD corresponding to each sensing area SA to entirely cover the light receiving part. Accordingly, it is possible to effectively reduce, alleviate, and/or improve deterioration of the photoelectric conversion element PD due to external light (for example, sunlight).

In one embodiment, each optical filter OF may have a thickness smaller than that of the color filter CF disposed in each emission area EA. Accordingly, the amount (or ratio) of light absorbed by the optical filter OF among the incident light (for example, light belonging to the visible light wavelength band) used for fingerprint sensing or the like is reduced or minimized, which makes it possible to sufficiently secure the amount of light received by the photoelectric conversion element PD. Accordingly, the sensitivity of the optical sensor PS may increase.

The first overcoat layer OC1 may be a capping layer for protecting the color filters CF and the optical filter OF, and may include an inorganic layer. For example, the first overcoat layer OC1 may contain silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or the like.

A window WDL may be disposed on the optical filter layer OFL. The window WDL may be formed of, for example, a glass substrate, a plastic substrate, or a protective film, and the material thereof is not limited thereto.

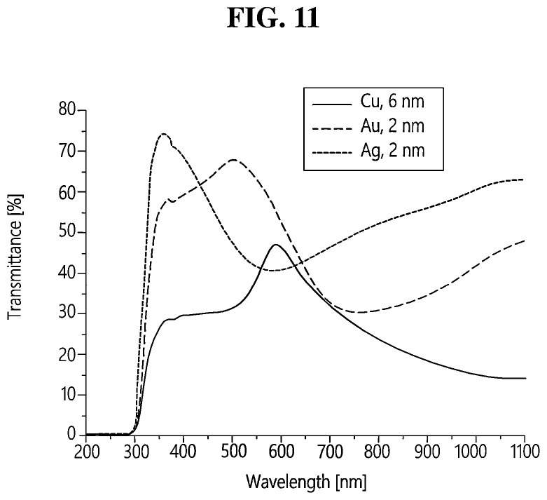

FIGS. 11 to 13 are graphs showing the light transmittance or the light absorption rate according to the material and the thickness of the optical filter OF. For example, FIGS. 11 to 13 show the light transmittance or the light absorption rate according to the material and/or the thickness of the metal thin film MTF in an embodiment in which the optical filter OF is the metal thin film MTF.

Referring to FIG. 11 in addition to FIGS. 1 to 10, the metal thin film MTF manufactured to have a thickness of 6 nm using copper (Cu), the metal thin film MTF manufactured to have a thickness of 2 nm using gold (Au), and the metal thin film MTF manufactured to have a thickness of 2 nm using silver (Ag) may exhibit different transmittances for incident light, and may have different peak wavelengths with the highest transmittance. Therefore, the metal thin film MTF may be manufactured with a material and a thickness satisfying a target transmission rate of light to be incident and a target absorption rate (or a blocking rate) of light to be blocked in consideration of the wavelength band (or the peak wavelength) and/or the type (for example, green light, red light, and/or blue light) of the incident light to be transmitted through the metal thin film MTF and incident on the photoelectric conversion element PD, and the wavelength band (for example, the wavelength band of approximately 300 nm or 350 nm or less) of the light to be blocked.

For example, when it is desired to generate a sensing signal in the optical sensor PS using the light of the first color (for example, green light) having a peak wavelength within a range of approximately 510 nm to approximately 550 nm, the optical filter OF may be formed of the metal thin film MTF manufactured to have a thickness of 2 nm using gold (Au). When it is desired to generate a sensing signal in the optical sensor PS using the light of the second color (for example, red light) having a peak wavelength within a range of approximately 610 nm to approximately 650 nm, the optical filter OF may be formed of the metal thin film MTF manufactured to have a thickness of 6 nm using copper (Cu). When it is desired to generate a sensing signal in the optical sensor PS using the light of the third color (for example, blue light) having a peak wavelength within a range of approximately 440 nm to approximately 480 nm, the optical filter OF may be formed of the metal thin film MTF manufactured to have a thickness of 2 nm using silver (Ag).

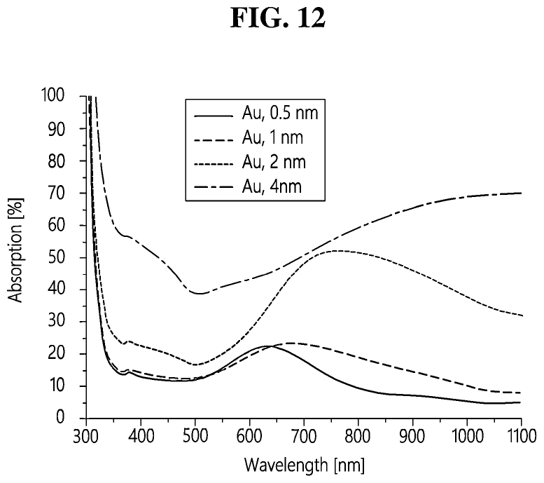

Referring to FIG. 12 in addition to FIGS. 1 to 11, even if the metal thin films MTF are made of the same material, the metal thin films MTF may exhibit different characteristics of light absorption depending on thicknesses thereof. For example, the metal thin films MTF manufactured to have thicknesses of 0.5 nm, 1 nm, 2 nm, and 4 nm using gold (Au) may exhibit different light absorption rates (or light blocking rates corresponding thereto).

Therefore, when the material of the metal thin film MTF is selected, the thickness of the metal thin film MTF may be appropriately adjusted or selected in consideration of the wavelength band (or the peak wavelength) and/or the type of light to be transmitted through the metal thin film MTF and incident on the photoelectric conversion element PD, and the wavelength band of light to be blocked. In one embodiment, the material and the thickness of the metal thin film MTF may be selected in consideration of the light transmittance and/or the absorption rate for each wavelength band within a thickness range of approximately 10 nm or less. For example, in the case of forming the metal thin film MTF using gold (Au), in order to prevent or minimize the loss of incident light to be used for generating a sensing signal, the metal thin film MTF may be formed to have a thickness of 2 nm or less so that the light absorption rate in the wavelength band (for example, the visible light wavelength band) of approximately 350 nm or more may be reduced or minimized.

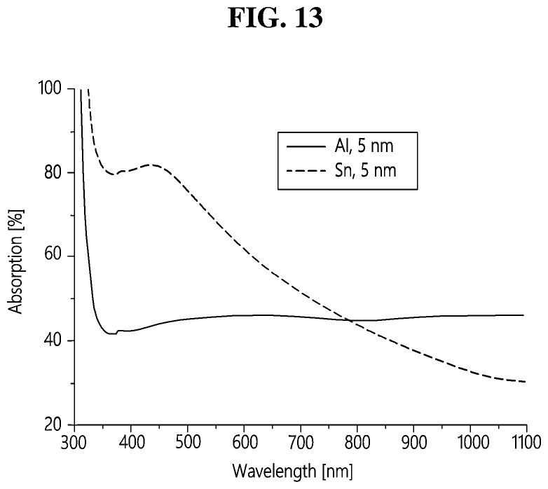

Referring to FIG. 13 in addition to FIGS. 1 to 12, even when the metal thin films MTF are formed with the same thickness, the metal thin films MTF may exhibit different characteristics of light absorption depending on materials thereof. For example, the metal thin film MTF manufactured to have a thickness of 5 nm using aluminum (Al) and the metal thin film MTF manufactured to have a thickness of 5 nm using tin (Sn) may exhibit different light absorption rates (or light blocking rates corresponding thereto).

Therefore, when the thickness of the metal thin film MTF is selected, an appropriate material may be selected among materials that may be used for the metal thin film MTF in consideration of the wavelength band (or the peak wavelength) and/or the type of light to be transmitted through the metal thin film MTF and incident on the photoelectric conversion element PD and the wavelength band of light to be blocked. For example, in the case of forming the metal thin film MTF with a thickness of approximately 5 nm, in order to prevent or minimize the loss of incident light to be used for generating a sensing signal, the metal thin film MTF may be formed using aluminum (Al) instead of using tin (Sn).

As described above, the light transmittance and the absorption rate of the metal thin film MTF may vary depending on the material and the thickness of the metal thin film MTF. Further, the wavelength band (or peak wavelength) of light transmitted through the metal thin film MTF and the wavelength band (or peak wavelength) of light absorbed and/or blocked by the metal thin film MTF may vary depending on the material and the thickness of the metal thin film MTF. Therefore, the metal thin film MTF may have a material and a thickness selected to satisfy the wavelength band of light to be transmitted by the metal thin film MTF and a target transmittance thereof, and the wavelength band of light to be absorbed and/or blocked by the metal thin film MTF and a target absorption rate (or blocking rate) thereof.

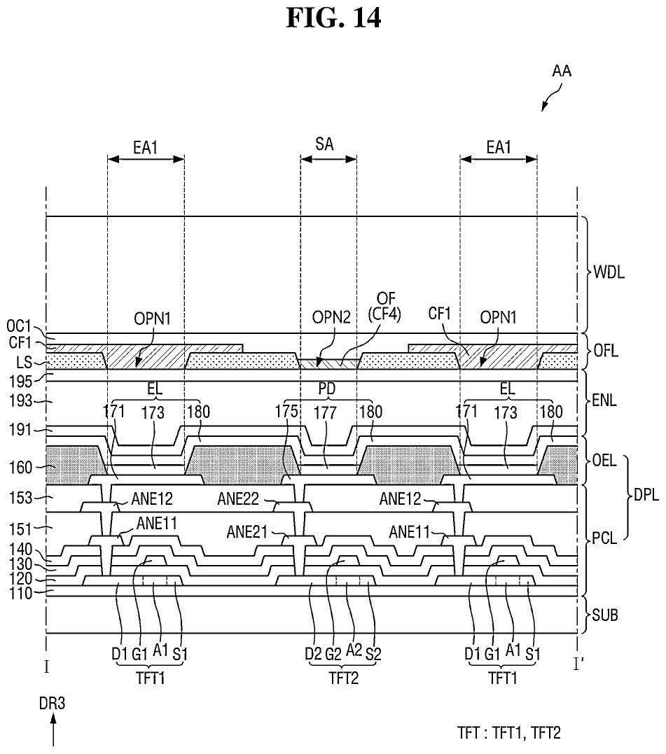

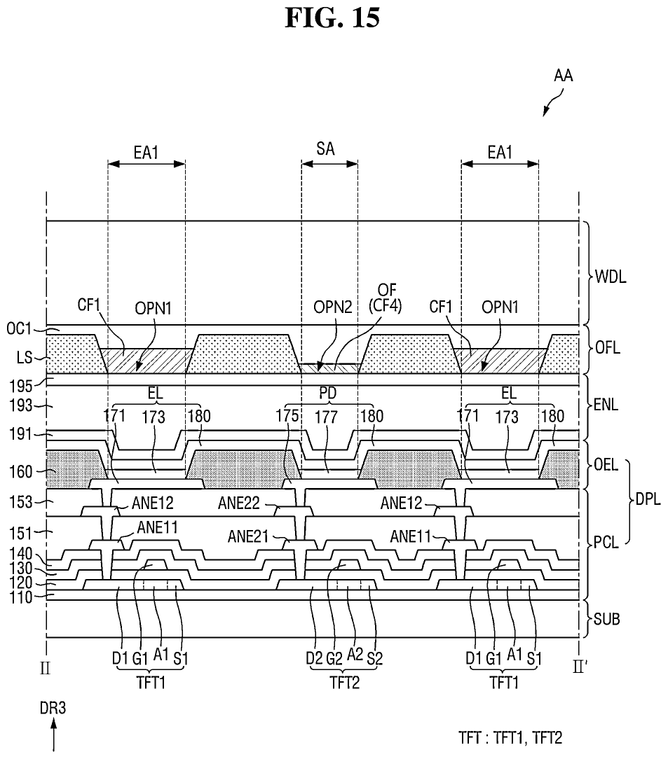

FIG. 14 is a cross-sectional view showing an example of a cross section of the display device 1 taken along line I-I′ of FIGS. 6 and 8. FIG. 15 is a cross-sectional view showing an example of a cross section of the display device 1 taken along line II-II′ of FIGS. 7 and 8. For example, FIGS. 14 and 15 show cross sections of modified embodiments of the embodiments of FIGS. 9 and 10 in relation to the optical filter layer OFL provided in the active area AA of the display device 1.

Referring to FIGS. 14 and 15 in addition to FIGS. 1 to 10, the optical filter OF disposed in each sensing area SA may include a color filter material of a specific color. For example, each optical filter OF may include a color filter (hereinafter, referred to as “fourth color filter CF4”) for selectively transmitting light of a specific color or a wavelength band corresponding thereto, or may be the fourth color filter CF4.

In one embodiment, the fourth color filter CF4 may be a color filter of the same type and/or color as that of at least one of the color filters CF disposed in the emission area EA. For example, when it is desired to generate a sensing signal using the light of the first color (for example, green light) emitted from the first emission area EA1 of the first color pixel PX1, the fourth color filter CF4 may be the first color filter (for example, green color filter) for selectively transmitting light of the first color. In one embodiment, the fourth color filter CF4 may be formed simultaneously with at least one of the color filters CF (for example, the first color filters CF) disposed in the emission area EA.

In one embodiment, the fourth color filter CF4 may have a thickness smaller than those of the color filters CF (for example, the first, second, and third color filters CF1, CF2, and CF3) disposed in each of the emission areas EA. Accordingly, it is possible to effectively absorb and/or block light of a specific wavelength band (for example, a wavelength band of approximately 300 nm or less or a wavelength band of approximately 350 nm or less) while reducing or minimizing the loss of incident light to be used for generating a sensing signal.

In one embodiment, the fourth color filter CF4 may be entirely disposed on the light receiving part of the photoelectric conversion element PD. For example, the fourth color filter CF4 may be entirely disposed in the second opening OPN2. Accordingly, the deterioration of the photoelectric conversion element PD due to external light or the like may be effectively reduced, alleviated, and/or improved.

As described above, the display device 1 according to the embodiments includes the photoelectric conversion element PD and the optical filter OF disposed on the photoelectric conversion element PD. The optical filter OF, which is a filter for transmitting light (for example, visible light) of some wavelength bands including light emitted from the light emitting element EL and absorbing and/or blocking short-wavelength light (for example, short-wavelength external light belonging to the wavelength band of approximately 300 nm or less or approximately 350 nm or less) of a specific wavelength band or less, may be, for example, a metal thin film or a color filter. The optical filter OF may be a thin film having a thickness smaller than that of the color filter CF disposed on the light emitting element EL, and thus may have a higher light transmittance with respect to visible light.

In accordance with embodiments, the deterioration of the photoelectric conversion element PD due to external light or the like may be reduced, alleviated, and/or improved while ensuring a sufficient amount of light received by the photoelectric conversion element PD. Accordingly, the reliability of the photoelectric conversion device PD and the optical sensor PS including the same may be increased.

In concluding the detailed description, those skilled in the art will appreciate that many variations and modifications can be made to the embodiments without substantially departing from the principles of the present inventive concept. Therefore, the disclosed embodiments of the inventive concept are used in a generic and descriptive sense only and not for purposes of limitation.

What is claimed is:

1. A display device comprising:
an active area comprising an emission area and a sensing area;
an optical element layer comprising a light emitting element located in the emission area and a photoelectric conversion element located in the sensing area;
a light blocking member disposed on the optical element layer, and comprising a first opening disposed in an area corresponding to the emission area and a second opening disposed in an area corresponding to the sensing area;
a color filter located in the first opening and overlapping the light emitting element; and
an optical filter located in the second opening and overlapping the photoelectric conversion element,
wherein the optical filter is entirely disposed in the second opening and has a thickness smaller than that of the color filter.

2. The display device of claim 1, wherein the optical filter comprises a metal thin film transmitting light corresponding to a wavelength band of light emitted from the emission area.

3. The display device of claim 2, wherein the metal thin film has a thickness of 10 nm or less.

4. The display device of claim 2, wherein the metal thin film contains at least one metal selected from the group consisting of copper (Cu), gold (Au), silver (Ag), nickel (Ni), titanium (Ti), vanadium (V), and aluminum (Al).

5. The display device of claim 1, further comprising a pixel comprising the light emitting element and emitting light of a first color in the emission area,
wherein the color filter is a color filter of the first color which selectively transmits light of the first color, and
wherein the optical filter comprises a color filter of the first color which selectively transmits light of the first color.

6. The display device of claim 5, wherein the pixel emits green light, and
wherein the color filter and the optical filter are green color filters.

7. The display device of claim 5, wherein the active area comprises a pixel column in which the pixel and another pixel which emit light of the first color are arranged, and
wherein the sensing area is disposed between the emission areas of the pixel and the another pixel.

8. The display device of claim 1, wherein the color filter and the optical filter are disposed on a same layer above the optical element layer.

9. The display device of claim 1, further comprising:
a panel circuit layer disposed below the optical element layer, and comprising a pixel transistor connected to the light emitting element and a sensor transistor connected to the photoelectric conversion element; and
a substrate disposed below the panel circuit layer.

10. The display device of claim 9, wherein the light emitting element and the photoelectric conversion element are disposed on a same layer above the substrate.

11. A display device comprising:
a first pixel comprising a light emitting element located in a first emission area;
an optical sensor comprising a photoelectric conversion element located in a sensing area disposed adjacent to the first emission area;
a first color filter located in the first emission area and disposed on the light emitting element; and
an optical filter located in the sensing area and disposed on the photoelectric conversion element,
wherein the optical filter entirely covers a light receiving part of the optical sensor disposed corresponding to the sensing area, and has a thickness smaller than that of the first color filter.

12. The display device of claim 11, wherein the optical filter comprises a metal thin film transmitting light corresponding to a wavelength band of light emitted from the first emission area.

13. The display device of claim 12, wherein the metal thin film has a thickness of 10 nm or less.

14. The display device of claim 12, wherein the metal thin film contains at least one metal selected from the group consisting of copper (Cu), gold (Au), silver (Ag), nickel (Ni), titanium (Ti), vanadium (V), and aluminum (Al).

15. The display device of claim 11, further comprising:
a second pixel comprising a light emitting element located in a second emission area;
a third pixel comprising a light emitting element located in a third emission area;
a second color filter located in the second emission area and disposed on the second pixel; and
a third color filter located in the third emission area and disposed on the third pixel,
wherein the first pixel, the second pixel, and the third pixel emit light of a first color, light of a second color, and light of a third color, respectively, and
wherein the first color filter, the second color filter, and the third color filter are color filters which selectively transmit light of the first color, light of the second color, and light of the third color, respectively.

16. The display device of claim 15, wherein the optical filter comprises a fourth color filter which selectively transmits one of light of the first color, light of the second color, and light of the third color and has a thickness smaller than those of the first color filter, the second color filter, and the third color filter.

17. The display device of claim 11, further comprising:
an optical element layer comprising the light emitting element and the photoelectric conversion element;
an optical filter layer disposed on the optical element layer, and comprising the first color filter and the optical filter; and
a substrate disposed below the optical element layer,
wherein the first color filter and the optical filter are disposed on a same layer on a surface of the substrate.

18. The display device of claim 17, further comprising a light blocking member provided in the optical filter layer, and surrounding the first emission area and the sensing area in a plan view.

19. The display device of claim 18, wherein the light blocking member comprises a first opening disposed in an area corresponding to the first emission area and a second opening disposed in an area corresponding to the sensing area,
wherein the first color filter is entirely disposed in the first opening, and
wherein the optical filter is entirely disposed in the second opening.

20. The display device of claim 18, wherein the optical filter has a thickness smaller than that of the light blocking member.
